(19) United States
(12) Patent Application Publication
(10) Pub. No.: US 2012/0266949 A1
(43) Pub. Date: Oct. 25, 2012

(54) ELONGATE SOLAR CELL AND EDGE CONTACT

(75) Inventors: Andrew William Blakers, Aranda (AU); Klaus Johannes Weber, Aranda (AU); Evan Franklin, Downer (AU); Sanju Prakash Deenapanray, Quatre Bornes (MU); Olly Powell, Devon Park (AU); Matthew Stocks, Boise, ID (US)

(73) Assignee: Transform Solar Pty Ltd., Adelaide (AU)

(21) Appl. No.: 13/264,976

(22) PCT Filed: Apr. 19, 2010
(86) PCT No.: PCT/AU2010/000433

§ 371 Date: Mar. 8, 2012

(30) Foreign Application Priority Data
Apr. 17, 2009 (AU) 2009901653

(51) Int. Cl. H01L 31/0224; H01L 31/18

(52) U.S. Cl. 136/256; 438/98; 257/E31.113

(57) ABSTRACT

An elongate solar cell, comprising a semiconductor body having two mutually opposed faces, at least one of the faces being an active face for receiving incident light, and two mutually opposed edges orthogonal to the faces, the edges comprising electrical contacts thereon for conducting electrical current generated by the solar cell from the light; wherein the electrical contact to at least one of the edges includes an electrically conductive material that contacts only a fractional portion of the at least one edge of the semiconductor body to improve the performance of the solar cell.

### TECHNICAL FIELD

The present invention relates to an improved form of elongate solar cell and an improved method for fabricating elongate solar cells.

### BACKGROUND

Any discussion of the background art throughout the specification should in no way be considered as an admission that such background art is prior art, nor that such background art is widely known or forms part of the common general knowledge in the field.

The reference in this specification to any prior publication (or information derived from it), or to any matter which is known, is not, and should not be taken as an acknowledgment or admission or any form of suggestion that prior publication (or information derived from it) or known matter forms part of the common general knowledge in the field of endeavour to which this specification relates.

In this specification, the term “elongate solar cell” refers to a solar cell 100 as shown schematically in FIG. 1 being of generally parallelepiped form with mutually opposed edges 101 and 101a, mutually opposed faces 103 and 103a and mutually opposed ends 105 and 105a. The cell 100 generally has a high aspect ratio in that its length l is substantially greater (typically some tens to hundreds of times larger) than its width w and its thickness t. Additionally, the zo width w of an elongate solar cell 100 is substantially greater (typically four to one hundred times larger) than its thickness t. The length l and width w of an elongate solar cell 100 define the maximum available active or useable surface area for photovoltaic power generation (the active “face” or “faces” 103 and 103a of the solar cell), whereas the length l and thickness t of an elongate solar cell 100 define the optically inactive longitudinal surfaces or “edges” 101 and 101a of the cell 100 that are used to make electrical contact to the cell. A typical elongate solar cell is l≈10-120 mm long, w≈0.3-3 mm wide, and t≈10-200 microns thick, although the present invention is applicable to all elongate solar cells and is not to be construed as being limited to elongate solar cells having any particular dimensions.

Elongate solar cells can be produced by processes such as those described in International Patent Application Publication No. WO 02/45143 (“the Sliver patent application”). That document describes processes for simultaneously producing a large number of thin (generally <150 μm) elongate silicon substrates from a single standard silicon wafer, whereby the number and dimensions of the resulting thin elongate substrates are such that the total useable surface area is greater than that of the original silicon wafer. Such elongate substrates are also referred to as Sliver substrates. The word “SLIVER” is a registered trademark of Origin Energy Solar Pty Ltd, Australian Registration No. 933476. The Sliver patent application also describes processes for forming an individual solar cell from each sliver substrate, the resulting elongate solar cells being referred to as ‘Sliver solar cells’. However, the word ‘sliver’ generally refers to a sliver substrate that may or may not incorporate one or more solar cells.

In general, elongate solar cells can be single-crystal solar cells or multi-crystalline solar cells formed on elongate substrates using essentially any solar cell manufacturing process. As shown in FIG. 2, elongate substrates are preferably formed in a batch process by is machining (for example by anisotropic wet chemical etching) a series of parallel elongate rectangular slots or openings 202 of a selected width (wₛ) completely through a silicon wafer 204 of thickness w so that the unetched silicon 206 strips with thickness t remaining between the newly formed openings 202 defines a corresponding series of parallel elongate parallelepiped substrates or ‘slivers’ 206 of silicon. The length l of the slots 202 is generally less than, but similar to, the diameter of the wafer 204 so that the elongate substrates or slivers 206 remain joined together by the remaining peripheral portion 208 of the wafer, referred to as the wafer frame 208. Each elongate substrate 206 is considered to have two longitudinal edges 210 and 210a with thickness t which are coplanar with the two wafer surfaces, two (newly formed) faces 212 and 212a perpendicular to the wafer surface with width w (i.e. the same as that of the wafer thickness), and two ends 214 and 214a, which initially remain attached to the wafer frame 208. In particular arrangements, the thickness of the elongate substrates (strips of silicon remaining after the machining of the slots) and the slot width are selected for division of the wafer such that the thickness of the wafer (corresponding to the width, w, of the elongate substrate) is greater than the sum of the strip thickness and the slot width (w>t+wₛ) so that the total surface area of the faces 212 and 212a of all the elongate substrates formed by the manufacturing process is greater than that of the surface area of the top and bottom faces of the semiconductor wafer.

Also as shown in FIG. 2, solar cells can be partially formed from the elongate substrates 206 while they remain retained by the wafer frame 208; the resulting elongate substrates 206 can then be separated from each other and from the wafer frame 208, and further processing performed if necessary, to provide a set of individual elongate solar cells. A large number of these sliver solar cells can be electrically interconnected and assembled together to form a solar power module, concentrator receiver, or other photovoltaic device.

When elongate substrates are formed in this way, the transverse width of the elongate slots (wₛ) and the thickness (t) of the elongate silicon substrates (slivers) are in the plane of the wafer surface, and each sliver/slot pair effectively requires a surface area of l×wₛ×t of the wafer surface, where 1 is the length of the elongate substrate. For example, if the width of the slot and the substrate thickness are both about 0.05 mm, then each sliver/slot pair effectively requires a surface area of 1×0.1 mm of the wafer surface. However, due to the thickness of the silicon wafer w (typically between ≈0.3 to 3 mm), the surface area of each of the two newly formed faces of the sliver (perpendicular to the wafer surface) is l×w (where w ˜0.3 to 3 mm), thus providing an increase in useable surface area of the wafer by a factor of between 5 to 30 relative to the original wafer surface (neglecting any useable surface area of the wafer frame). The thickness of the slot, wₛ, can be varied between about 0.005 and 0.1 mm, for example, about 0.005, 0.006, 0.007, 0.008, 0.009, 0.01, 0.015, 0.02, 0.025, 0.03, 0.035, 0.04, 0.045, 0.05, 0.055, 0.06, 0.065, 0.07, 0.075, 0.08, 0.085, 0.09, 0.095 or about 0.1 mm. Also, the thickness t of the elongate substrates (strips) in the plane of the wafer surface may also be varied between about 0.001 and about 0.2 mm, for example, about 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.1, 0.15, or about 0.2 mm. Also, the thickness of the wafer may also vary between about 0.1 to about 5 mm, for example about 0.1, 0.2, 0.3, 0.4, 0.5, 0.6, 0.7, 0.8, 0.9, 1.0, 1.5, 2.0, 2.5, 3.0, 3.5, 4.0, 4.5, or about 5 mm in accordance with requirements and manufacturing tolerances. Accordingly, the increase in the useable surface area of the wafer may be increased further. The length of the elongate substrates may be similar to that of the diameter of the wafer, or may be less, depending on the orientation of the slots formation (e.g. a plurality of groups of slots may be formed at different orientations and/or length in the wafer to form a corresponding plurality of groups of substrates). The length of the substrate may typically be in the range of about 20 mm to about 100 mm, although longer cells may also be formed, e.g. up to about 150 or 200 mm or more, if larger diameter wavers are used.

The fabrication of an elongate or Sliver solar cell involves several steps, including the formation of one or more p-n junctions for the collection of photocurrent generated in the device; the passivation of most or all of the surfaces of the silicon strip with a dielectric or insulating layer; and the formation of electrical contacts to the p-type and n-type regions of the device. Additional optional but preferred steps include the application of an antireflection coating to one or both faces in order to reduce the reflection of light from the silicon strips, and the texturing (roughening) of one or more of the faces of each strip in order to reduce the reflection of light and also to confine light within the silicon strip.

Insulating coatings, usually fabricated from dielectric materials, are placed on most it) surfaces of efficient solar cells for the purpose of decreasing surface recombination of electrons and holes, reducing reflection losses (by acting as an antireflection coating), and preventing metal from contacting silicon except where desired.

In practice, more than one of the above steps can be effected by a single process step. For example, the application of a layer of silicon nitride by plasma-enhanced chemical vapour deposition (PECVD) can serve to both passivate a silicon surface and also to provide an antireflection coating.

It is generally desirable to be able to fabricate solar cells with high conversion efficiency. Consequently, it is preferred that the solar cells be made from a material with a high minority carrier diffusion, length, have well-passivated surfaces, and have good optical properties.

The metal contacts to a solar cell should generally occupy a small area consistent with obtaining adequately low contact resistance. The reason for this is that these contact regions have high minority carrier recombination rates. For a given metal-semiconductor contact area, the amount of recombination can be minimised by heavily doping the surface beneath the metal contact with an appropriate n-type or p-type dopant. However, the heavily doped regions themselves are regions of elevated recombination rates, and so their area should be minimised. In the case of a typical sliver cell, the edges constitute about 5% of the total surface area of the cell. Thus heavily doping and metallising an entire edge meets the criterion that such regions occupy a small fraction of the surface area of the cell.

The cost of fabricating a solar cell will generally be reduced if the cell fabrication process sequence is short, delivers a high yield of efficient cells, and uses a minimum of consumables and expensive process equipment. For a given wafer throughput, a more complex process will entail a larger fabrication facility, more process equipment, and higher costs for maintenance, consumables, and waste disposal. A long fabrication process will typically have a lower yield than a similar but shorter process.

As in other applications of semiconductor processing, the processing steps involved in the manufacture of solar cells from semiconductor wafers are often found to be non-ideal in practice, and consequently can give rise to imperfect and/or unintended structures or artefacts, referred to generically herein as “processing defects”, that degrade the performance of the resulting solar cells. For example, some processing defects can cause electrical shunting paths (short circuits) to form between n-type doped regions and p-type doped regions of an elongate solar cell, and/or between the metal contacts to those doped regions. Some processing defects can cause excessive recombination of photogenerated carriers within the cell, thus decreasing the efficiency of the cell. Some processing defects can allow n-type and/or p-type dopants to appear in regions where they were not intended to be. They can also allow metal to contact the semiconductor in unintended regions, which may form shunt paths (short circuits).

It is desired to provide an elongate solar cell and a method for producing an elongate solar cell that alleviate one or more difficulties of the prior art, or that at least provide a useful alternative.

### SUMMARY OF THE INVENTION

In any of the aspects or arrangements described herein, the apparatus, system or method may also comprise one or more of any of the following either taken alone or in any suitable combination.

In accordance with a first aspect, there is provided an elongate solar cell. The elongate solar cell may comprise a semiconductor body comprising two mutually opposed faces. At least one of the mutually opposed faces may be an active face for receiving incident light. The semiconductor body may further comprise two mutually opposed edges substantially orthogonal to the mutually opposed faces. The edges may comprise electrical contacts thereon for conducting electrical current generated by the solar cell from the incident light. The electrical contact to at least one of the edges may comprise an electrically conductive material that contacts only a portion of the at least one edge of the semiconductor body to improve the performance of the solar cell.

In an arrangement of the first aspect, there is provided an elongate solar cell, comprising a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light; wherein the electrical contact to at least one of the edges includes an electrically conductive material that contacts only a fractional portion of the at least one edge of the semiconductor body to improve the performance of the solar cell.

The fractional portion of the edge contacted by the electrically conductive material may comprise less then 100% of the surface area of the edge and may be less than or substantially less than 99% of the surface area of the edge. In particular arrangements, the electrically conductive material may contact a surface area of the edge comprising less than 100% of the surface area of the edge, and may be between about 1% and about 99%, or alternatively between about, 1% and 95%, 1% and 90%, 1% and 80%, 1% and 70%, 1% and 60%, 1% and 50%, 1% and 40%, 1% and 30%, 1% and 20%, 1% and 10%, 1% and 5%, or between 10% and 90%, 10% and 75%, 10% and 50%, 10% and 25%, 25% and 90%, 25% and 75%, 25% and 50%, 50% and 98%, 50% and 90%, or between about 50% and about 75%. For example, the electrically conductive material may contact about 1%, 5%, 10%, 15%, 20%, 25%, 30%, 35%, 40%, 45%, 50%, 55%, 60%, 65%, 70%, 75%, 80%, 85%, 90%, 95%, 96%, 97%, 98% or about 99% of the surface area of the edge.

By arranging for the electrically conductive material to contact only a relatively small portion of the edge of the semiconductor body, the impact of processing defects or other factors that degrade the performance of the solar cell is correspondingly reduced. Thus a solar cell in accordance with the present invention has improved performance relative to an otherwise identical solar cell but in which the electrically conductive material contacts substantially all of the at least one edge of the cell.

The electrically conductive material contacting the edge of the semiconductor body may be of elongate form and may be substantially centrally disposed along a longitudinal axis of the at least one edge of the semiconductor body. The electrically conductive material may contact the semiconductor body at mutually spaced contact regions of the edge. The regions of the edge not contacted by the electrically conductive material may be contacted by a dielectric material. The contact regions may be of elongate form. The contact regions may be of elongate form, mutually parallel, and may be inclined to a longitudinal axis of the at least one edge. The contact regions may be of non-elongate form and distributed over the at least one edge.

In a particular arrangement, the electrically conductive material may contact less than about 100%, and may contact between about 0.01% and about 100% or between about 0.01% and 99%, and may contact about 0.01%, 0.05%, 1%, 5%, 10%, 25%, 50%, 75%, 90%, 95%, or about 99% of the surface area of the edge of the semiconductor body (where the edge surface area is the length, l, of the elongate body multiplied by its thickness, t).

In a further arrangement, the electrically conductive material may contact approximately equal to or less than about one half (≈≦50%) of the surface area of the edge of the semiconductor body. Alternatively, the electrically conductive material may contact substantially less than one half (<<50%) of the surface area of the edge of the semiconductor body. The electrically conductive material may contact less than or substantially less than about 10% (≈<10% or <<10%) of the surface area of the edge of the semiconductor body. The electrically conductive material may contact less than or substantially less than about 1% (≈<1% or <<1%) of the surface area of the edge of the semiconductor body. The electrically conductive material may contact between about 0.01% and about 10% of the surface area of the edge of the semiconductor body, or alternatively between about 0.01% and about 5%, or between 0.01% to 10%, 0.01% to 25%, 0.01% to 50%, 1% to 5%, 1% to 10%, 1%, to 25%, 1% to 50%, 5% to 10%, 5% to 25%, 5% to 50%, 10% to 25%, 10% to 50%, or between about 25% to about 50%, for example about 0.01%, 0.02%, 0.03%, 0.04%, 0.05%, 0.06%, 0.07%, 0.08%, 0.09%, 1%, 2%, 3%, 4%, 5%, 6%, 7%, 8%, 9%, 10%, 15%, 20%, 25%, 30%, 35%, 40%, 45%, or about 50%.

In a still further arrangement, the electrically conductive material may contact approximately equal to or greater than about one half (≈≧50%) of the surface area of the edge of the semiconductor body. Alternatively, the electrically conductive material may contact substantially greater than one half (>>50%) of the surface area of the edge of the semiconductor body. The electrically conductive material may contact greater than or substantially greater than about 75% (≈>75% or >>75%) of the surface area of the edge of the semiconductor body. The electrically conductive material may contact less than or substantially greater than about 90% (≈>90% or >>90%) of the surface area of the edge of the semiconductor body. The electrically conductive material may contact between about 50% and about 99% of the surface area of the edge of the semiconductor body, or alternatively between about 50% and about 95%, or between 50% to 90%, 50% to 75%, 75% to 99%, 75% to 90%, 75% to 80%, 80%, to 99%, 80% to 95%, 80% to 90%, 90% to 99%, 90% to 95% or between about 95% to about 99%, for example about 50%, 55%, 60%, 65%, 7%, 75%, 80%, 85%, 90%, 91%, 92%, 93%, 4%, 95%, 96%, 97%, 98%, or about 99%.

In a second aspect, there is provided a process for producing an elongate solar cell. The elongate solar cell may comprise a semiconductor body comprising two mutually opposed faces. At least one of the faces may be an active face for receiving incident light. The elongate solar cell may further comprise two mutually opposed edges substantially orthogonal to the faces. The edges may comprise electrical contacts thereon for conducting electrical current generated by the solar cell from the light. The process for producing the elongate solar cell may comprise forming an electrical contact to at least one of the edges The electrical contact may comprise an electrically conductive material. The electrically conductive material may contact only a fractional portion of the at least one edge of the semiconductor body to improve the performance of the solar cell. The fractional portion may be a relatively small portion of the at least one edge.

In an arrangement of the second aspect, there is provided a process for producing an elongate solar cell, the elongate solar cell comprising a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light; the process comprising forming an electrical contact to at least one of the edges, the electrical contact comprising an electrically conductive material that contacts only a relatively small portion of the at least one edge of the semiconductor body to improve the performance of the solar cell.

The process may further comprise forming the electrically conductive material in elongate form. The elongate formation of electrically conductive material may be substantially centrally disposed along a longitudinal axis of the at least one edge of the semiconductor body.

In a particular arrangement, the electrically conductive material may contact the semiconductor body at mutually spaced contact regions of the edge. The regions of the edge not contacted by the electrically conductive material may be contacted by a dielectric material. The contact regions may be of elongate form. The contact regions may be of elongate form, mutually parallel. The contact regions may be inclined to a longitudinal axis of the at least one edge. Alternatively, the contact regions may be of non-elongate form and may be distributed over the at least one edge.

The process may further comprise forming a dielectric or electrically insulating coating on the at least one edge of the semiconductor body. The coating may comprise one or more openings therein to expose a fractional portion of the at least one edge of the semiconductor body. The process may further comprise forming the electrically conductive material in the one or more openings to contact respective contact regions of the at least one edge exposed by the openings. The forming of the coating may comprise forming the one or more openings in an existing dielectric or electrically insulating coating. The coating may comprise a plurality of openings therein to expose respective regions of the at least one edge. The openings may be created using either a laser, a mechanical scribing process, an etch paste, or etching techniques such dry etch techniques, e.g. reactive ion etching or plasma etching, or other etching techniques as would be appreciated by the skilled addressee. The openings may be formed by any other means capable to remove portions of the coating including, for example, short pulses of ultra violet light generated by a laser, or by application of an etching paste to selectively remove portions of the coating without causing significant damage to the underlying semiconductor body.

The electrically conductive material may be deposited either by vacuum evaporation, screen printing, electroplating, electroless plating, inkjet printing, aerosol printing, or another deposition process. In some arrangements, the deposition method may be a directional process.

In the directional deposition process the electrically conductive material may be directed substantially perpendicular to the plane of the surface upon which the electrically conductive material is to be deposited (typically the edge of the cell). In other arrangements, electrically conductive material may be directed at an inclined angle to the surface upon which the electrically conductive material is to be deposited (typically the edge of the cell). In the inclined directional process, the electrically conductive material may be deposited both on the edge of the cell, and also on a portion of a contiguous or adjacent surface to the edge, such as for example at least one face of the cell.

The process may further comprise forming heterojunction electrical contacts within the openings.

The semiconductor body may comprise a background doping of a first polarity type (either p-type or n-type), and only one of the edges of the semiconductor body may comprise a surface doping layer of a second polarity type opposite to the first polarity type (either n-type or p-type respectively), wherein the openings are formed only on the edge having the surface doping layer of the second polarity type.

Alternatively, the semiconductor body may comprise a background doping of a first polarity type (either p-type or n-type), and only one of the edges of the semiconductor body may comprise a surface doping layer of the first polarity type (either p-type or n-type), wherein the openings are formed only on the edge having the surface doping layer of the first polarity type.

The openings may be formed as a plurality of substantially non-elongate openings. Alternatively, the openings may be formed as a plurality of elongate openings having longitudinal axes inclined to a longitudinal axis of the at least one edge.

The electrically conductive material may be a metal selected to form: 1) a good electrical contact to the one or more regions of the at least one edge of the semiconductor body exposed by the one or more openings, the one or more exposed regions comprising a surface doping layer of a first polarity type (either p-type or n-type) and a first dopant concentration; but 2) poor electrical contact to any regions exposed by any unintended openings in the coating and comprising a second doping concentration substantially different to the first doping concentration and/or comprising a surface doping layer of a second polarity type opposite to the first polarity type (either n-type or p-type respectively). The electrically conductive material of any one of the aspects of the invention disclosed herein may be a metal selected from the group comprising cobalt (Co), nickel (Ni), palladium (Pd), platinum (Pt), titanium (Ti), silver (Ag), aluminium (Al) or other suitable alternative as would be appreciated by the skilled addressee. Alternatively, the metal may be a compound or combination comprising, but not limited to, one or more metals selected from the group of Co, Ni, Pd, Pt, Ti, Ag, Al or other suitable metal.

The openings may be formed by depositing the electrically conductive material over the coating, and driving the electrically conductive material through the coating at mutually spaced locations to form the openings. The electrically conductive material may be driven through the coating only at mutually spaced regions of the coating by localised heating by a process comprising selectively heating corresponding mutually spaced regions of the electrically conductive material. The localised heating may be achieved using a directed laser beam.

Alternatively, the electrically conductive material may be deposited only at mutually spaced regions on the coating. This allows the electrically conductive material to be locally driven through the coating using a process of uniform heating such as furnace heating, for example.

The process may further comprise selectively doping only those regions of the at least one surface of the semiconductor body exposed by the openings, and forming the electrically conductive material to contact the resulting doped regions. The doped regions may intersect or abut at least one of the faces of the semiconductor body along only a fractional portion of the intersection of the at least one face with at least one corresponding edge of the semiconductor body to reduce the likelihood of the doped regions forming an electrical short to a doped region of the at least one corresponding edge. The fractional portion may be a relatively small portion of the intersection of the at least one face with at least one corresponding edge of the semiconductor body.

Advantageously, the electrically conductive material may include a dopant species, and the contact regions may be doped by selectively heating corresponding regions of the electrically conductive material formed over the dielectric coating to selectively drive the heated regions of the electrically conductive material through the dielectric coating to contact the edge of the semiconductor body and to drive the dopant species into the semiconductor body.

Alternatively, the electrically conductive material may include a dopant species, and zo the contact regions may be doped by selectively depositing the electrically conductive material at mutually spaced locations on the dielectric coating, and subsequently heating the electrically conductive material to drive it through the dielectric coating to contact the edge of the semiconductor body and to drive the dopant species into the semiconductor body.

Alternatively, the contact regions may be doped by laser chemical processing utilising a liquid-jet-guided laser beam in conjunction with a jet-liquid containing the desired dopant atoms. The liquid-jet-guided laser beam locally forms openings in the dielectric coating and at the same time dopes the exposed regions of the semiconductor body.

Alternatively, the contact regions may be doped by locally heating a material containing a dopant species using a laser without liquid guiding to drive the dopant species into the semiconductor body. If a dielectric layer is disposed between the doping material and the semiconductor body, it is found that the laser disrupts the dielectric layer to allow the dopant species to dope the corresponding regions of the semiconductor body.

The faces of each elongate solar cell may be doped with a dopant of a first polarity (either p-type or n-type), and an edge of the elongate solar cell doped discontinuously in mutually spaced doped regions with a dopant of a second polarity opposite to the first polarity (either n-type or p-type respectively), wherein the doped regions of the faces and the doped regions of the edge intersect or abut over only a relatively small portion of the length of each intersection of the edge and the corresponding face.

According to a third aspect, there is provided a process for producing an elongate solar cell. The elongate solar cell may comprise a semiconductor body comprising two mutually opposed faces. At least one of the faces may be an active face for receiving incident light. The elongate solar cell may further comprise two mutually opposed edges substantially orthogonal to the faces. The edges may comprise electrical contacts thereon for conducting electrical current generated by the solar cell from the light. The process may comprise forming a plurality of mutually spaced doped regions in at least one of the edges so that the at least one edge is doped discontinuously to improve the performance of the solar cell.

In an arrangement of the third aspect, there is provided a process for producing an elongate solar cell, the elongate solar cell comprising a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light; the process comprising forming a plurality of mutually spaced doped regions in at least one of the edges so that the at least one edge is doped discontinuously to improve the performance of the solar cell.

The at least one active face may comprise a doped region of a first polarity (either p-type or n-type) and the at least one edge is doped to form doped regions of a second polarity opposite to the first polarity (either n-type or p-type respectively), wherein the doped region of the at least one face intersects or abuts at least one of the oppositely doped regions of the at least one edge. The doped regions in the at least one edge may occupy only a fractional portion of the at least one edge.

In a particular arrangement, the doped regions in the at least one edge may occupy less than about 100% of the at least one edge, and may occupy between about 0.01% and about 100% or between about 0.01% and 99%, and may contact about 0.01%, 0.05%, 1%, 5%, 10%, 25%, 50%, 75%, 90%, 95%, or about 99% of the at least one edge.

In a further arrangement, the doped regions in the at least one edge may occupy a relatively small portion of the at least one edge and may occupy approximately equal to or less than about one half (≈≦50%) of the at least one edge.

Alternatively, the electrically conductive material may contact substantially less than one half (<<50%) of the surface area of at least one edge of the semiconductor body. The electrically conductive material may contact less than or substantially less than about 10% (≈<10% or <<10%) of the surface area of the at least one edge of the semiconductor body. The electrically conductive material may contact less than or substantially less than about 1% (≈<1% or <<1%) of the at least one edge.

In a still further arrangement, the doped regions in the at least one edge may occupy a relatively large portion of the at least one edge and may occupy approximately equal to or greater than about one half (≈≧50%) of the at least one edge.

Alternatively, the electrically conductive material may contact substantially greater than one half (>>50%) of the surface area of at least one edge of the semiconductor body. The electrically conductive material may contact greater than or substantially greater than about 75% (≈>75% or >>75%) of the surface area of the at least one edge of the semiconductor body. The electrically conductive material may contact greater than or substantially greater than about 90% (≈>90% or >>90%) of the surface area of the edge of the semiconductor body.

The doped regions in the at least one edge may form respective p-n junctions with the doped region of the corresponding at least one face.

The process may further comprise heating the elongate solar cell to lower the surface concentration of at least one of the doped regions of the faces and the doped regions of the at least one edge. The heating may reduce the reverse breakdown voltage of the p-n junctions.

According to a fourth aspect, there is also provided an elongate solar cell produced by any one of the above aspects.

According to a fifth aspect, there is provided an elongate solar cell. The elongate solar cell may comprise a semiconductor body comprising two mutually opposed faces. At least one of the faces may be an active face for receiving incident light. The elongate solar cell may further comprise two mutually opposed edges substantially orthogonal to the faces. The edges may comprise electrical contacts thereon for conducting electrical current generated by the solar cell from the light. At least one of the edges of the elongate solar cell may comprise a plurality of mutually spaced doped regions so that the at least one edge is doped discontinuously to improve the performance of the solar cell.

In an arrangement of the fifth aspect, there is provided an elongate solar cell, the to elongate solar cell comprising a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light; wherein at least one of the edges of the elongate solar cell comprises a plurality of mutually spaced doped regions so that the at least one edge is doped discontinuously to improve the performance of the solar cell.

The at least one active face may comprise a doped region of a first polarity (either p-type or n-type) and at least one of the edges is doped to form doped regions of a second polarity opposite to the first polarity (either n-type or p-type respectively), wherein the doped region of the at least one face intersects or abuts at least one of the doped regions of the at least one edge. The doped regions in the at least one edge may occupy a fractional portion of the at least one edge. The fractional portion may comprise less than 100% of the surface area of the at least one edge. The fractional portion may comprise between about 0.01% and about 99% of the surface area of the at least one edge. The fractional portion may comprise between about 0.01% and about 50% of the surface area of the at least one edge. The fractional portion may comprise between about 50% and about 99% of the surface area of the at least one edge. The doped regions in the at least one edge may form respective p-n junctions with the doped region of the corresponding at least one face.

It is an object of the present invention to substantially overcome or at least ameliorate one or more of the disadvantages of the prior art, or at least to provide a useful alternative to existing electrical contacts for elongate solar cells.

### BRIEF DESCRIPTION OF THE DRAWINGS

Arrangements of the elongate solar cells will now be described, by way of example only, with reference to the accompanying drawings, wherein:

FIG. 1 is a schematic perspective view of an isolated elongate solar cell, showing a section line A-A′;

FIG. 2 is a schematic perspective view of a set of prior art elongate semiconductor bodies or substrates retained within a semiconductor wafer frame, a quarter of which has been removed in order to view half of the elongate substrates;

FIG. 3 is a schematic cross-sectional view of an elongate solar cell (through the to section line A-A′ shown in FIG. 1) during production (prior to formation of the electrical contacts on the edges of the cell), illustrating the differently doped surface layers coated with a dielectric (typically SiO₂, where the semiconductor is Si);

FIGS. 4A to 4C are schematic cross-sectional views of the top-left corner of an idealised elongate solar cell at different stages of its production;

FIGS. 5A to 5C are schematic cross-sectional views corresponding to FIGS. 4A to 4C, but for a typical actual (i.e., non-idealised) elongate solar cell;

FIG. 6A is a schematic depiction of three (idealised) example cell structure options with full edge width metallic contacts for minimising the probability of shunting by the contact;

FIG. 6B is a schematic depiction of two (idealised) example cell structure options with fractional edge metallic contacts for minimising the probability of shunting by the contact;

FIG. 7 is a schematic illustration of the angled deposition of metal on elongate substrates;

FIG. 8 is a view of intermittent openings in a surface insulating dielectric layer, in this case orthogonal to the long axis of each sliver;

FIG. 9 is a view of a face and edge of a cell before (LHS) and after (RHS) thermal treatment, showing the n-type face doping extends onto the surface of the edge, causing a short circuit to appear between n and p type regions after metallisation, and the effect of thermal treatment to avoid the short-circuit;

FIG. 10 is a schematic diagram showing perspective and plan views of an edge of an elongate semiconductor body that is selectively doped along an elongate region centrally disposed along the longitudinal axis of the edge and spaced from the two faces of the semiconductor body that intersect the edge;

FIG. 11 is a schematic diagram showing a defect in the form of a pinhole in a dielectric coating causing an electrical short circuit between an oppositely doped edge and face, following angled evaporation of a metal contact. If the metal is discontinuous along the length of the edge, then the probability of including a pinhole within one of the metallised regions is correspondingly reduced

FIGS. 12A to 12C are schematic cross-sectional views of the edge of an elongate solar cell at different stages of its production to form a fractional edge contact;

FIGS. 13A to 13E are schematic cross-sectional views of the edge of an elongate solar cell depicting alternative fractional edge contacts;

FIGS. 14A to 14F are schematic cross-sectional views of a method for forming an elongate solar cell having fractional edge contacts.

### DEFINITIONS

The following definitions are provided as general definitions and should in no way limit the scope of the present invention to those terms alone, but are put forth for a better understanding of the following description.

Unless defined otherwise, all technical and scientific terms used herein have the same meaning as commonly understood by those of ordinary skill in the art to which the invention belongs. For the purposes of the present invention, the following terms are defined below.

The articles “a” and “an” are used herein to refer to one or to more than one (i.e. to at least one) of the grammatical object of the article. By way of example, “an element” refers to one element or more than one element.

The term “about” is used herein to refer to quantities that vary by as much as 30%, preferably by as much as 20%, and more preferably by as much as 10% to a reference quantity.

Throughout this specification, unless the context requires otherwise, the words “comprise”, “comprises” and “comprising” will be understood to imply the inclusion of a stated step or element or group of steps or elements but not the exclusion of any other step or element or group of steps or elements.

Although any methods and materials similar or equivalent to those described herein can be used in the practice or testing of the present invention, preferred methods and materials are described. It will be appreciated that the methods, apparatus and systems described herein may be implemented in a variety of ways and for a variety of purposes. The description here is by way of example only.

### DETAILED DESCRIPTION

As described above, when forming elongate or sliver solar cells from a wafer by etching parallel slots through a semiconductor wafer, the anisotropic etching process can cause undesirable structures that increase the probability that metal simultaneously contacts both n-type and p-type regions, thus causing an electrical shunt that short circuits the solar cell, thus degrading its efficiency or even rendering it inoperative.

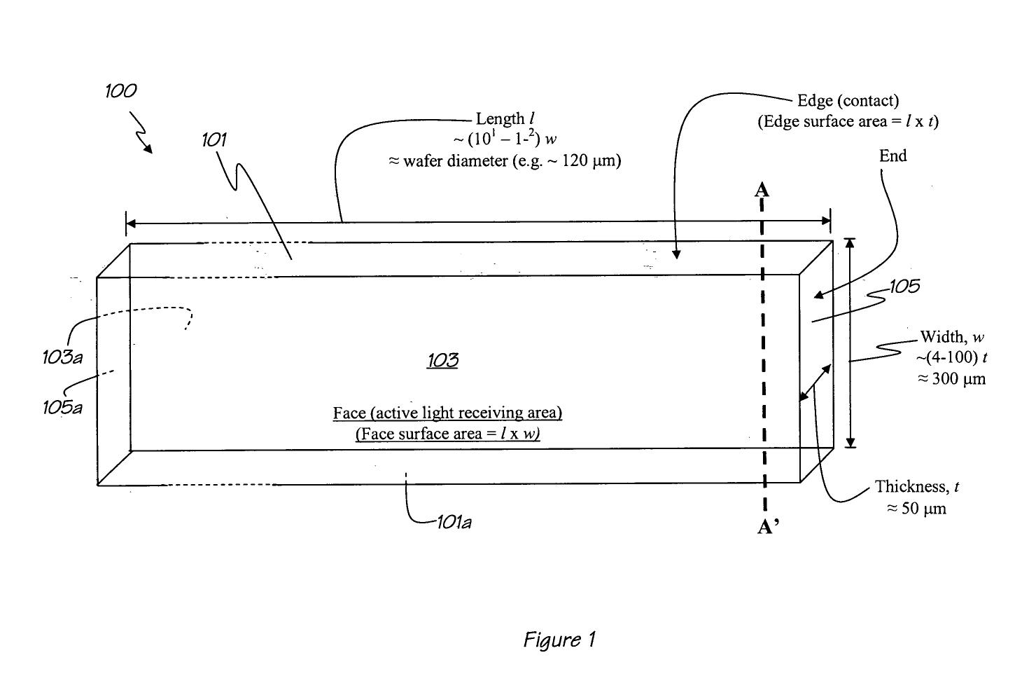

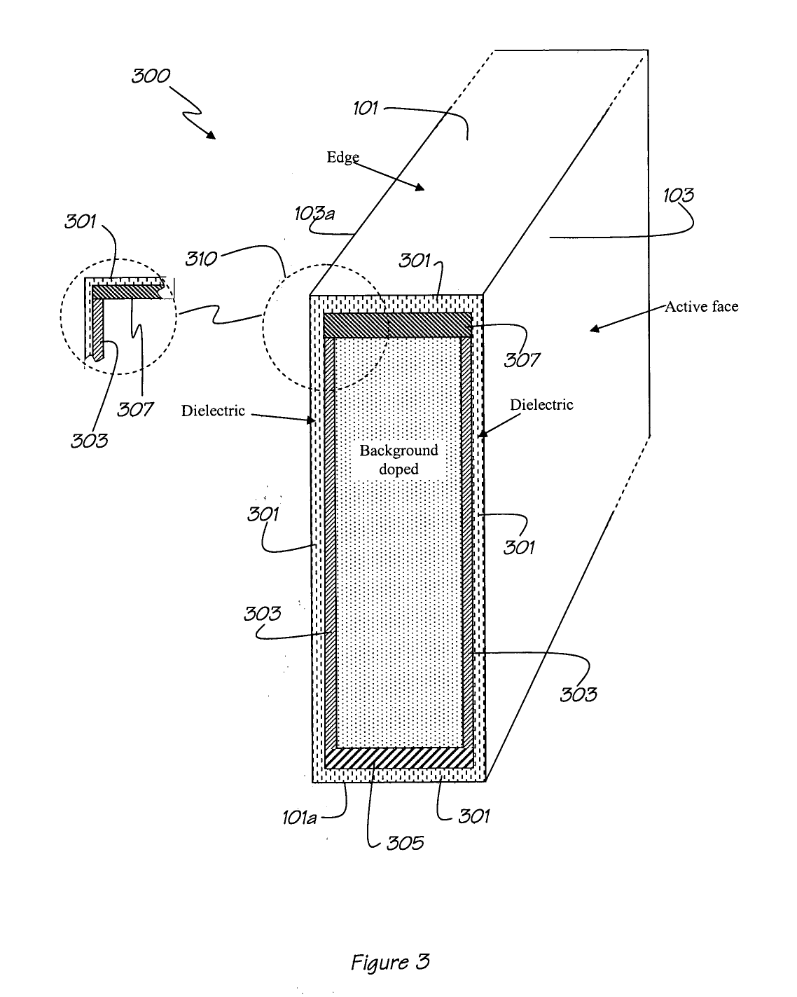

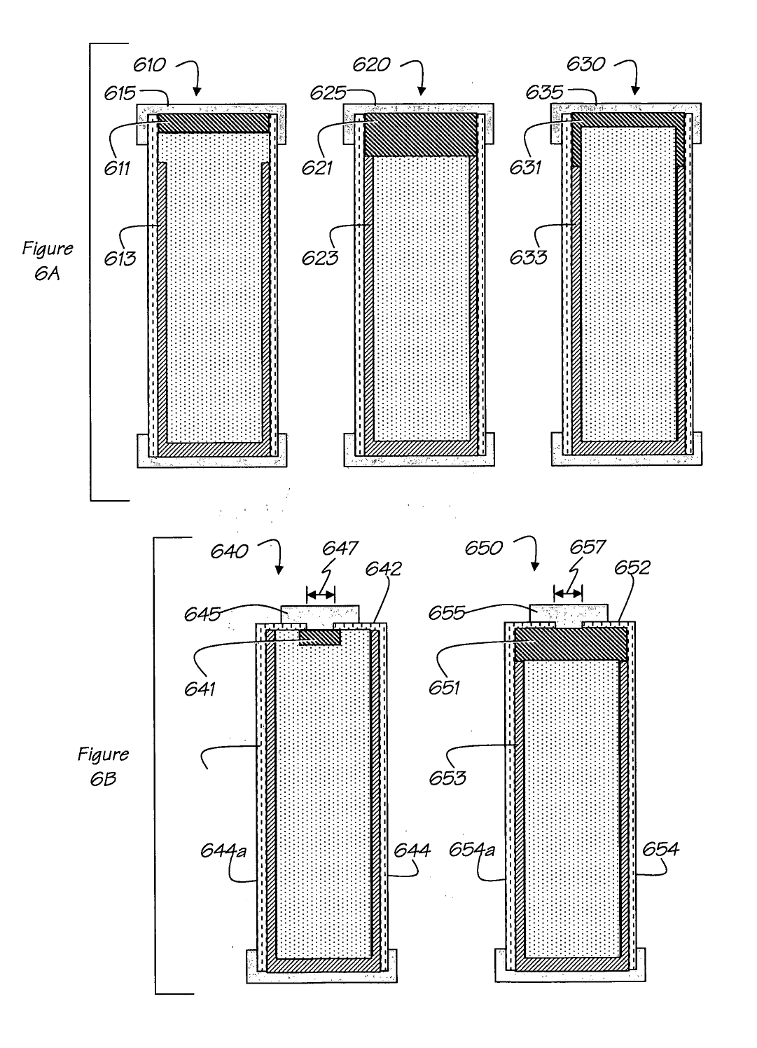

For example, FIG. 3 is a schematic cross-sectional view through a typical elongate solar cell 300 during its production prior to formation of the electrical contacts on edges 101 and 101a of the cell (the cross-section being through the section line A-A′ shown in FIG. 1), with both faces 103 and 103a and both edges 101 and 101a of the cell being coated with a layer of electrical insulator or dielectric 301. Suitable fractional edge electrical contacts for cell 300 are depicted with reference to FIGS. 6B, 8, 9, 10, 12C, 13A to 13E and 14E and 14F.

In the usual case where the solar cells are formed from the semiconductor silicon, the dielectric 301 is often SiO₂. Beneath the dielectric coating, the two opposed faces 103 and 103a of the cell 300 are lightly doped with a dopant species 303 of the opposite polarity type to that of the background doping of the silicon wafer from which the cell was formed. Typically, the starting wafer is lightly doped with a p-type dopant (e.g. boron), and the faces 303 are lightly doped with an n-type dopant (e.g. phosphorus). One of the two opposed edges 305 of the cell (the lower edge in FIG. 3) is also doped with the same dopant species (e.g. phosphorus) used to dope the two faces of the cell, but to a much higher concentration to facilitate a good Ohmic electrical contact to the cell. The other edge 307 of the cell is fairly heavily doped with a p-type dopant dopant species (e.g. boron) of the opposite polarity type to provide a highly doped p-type surface layer to facilitate good Ohmic contact to that edge. Alternatively, the starting wafer may be lightly doped with an n-type dopant (e.g. phosphorus), and the faces 303 are lightly p-doped with a p-type dopant (e.g. boron). One of the two opposed edges 305 of the cell (the lower edge in FIG. 3) is also doped with the same p-type dopant species (e.g. boron) used to dope the two faces of the cell, but to a much higher concentration to facilitate a good Ohmic electrical contact to the cell. The other edge 307 of the cell is fairly heavily doped with a n-type dopant species (e.g. phosphorus) of the opposite polarity type to provide a highly doped p-type surface layer to facilitate good Ohmic contact to that edge 307. Alternative n-type dopants may also be used instead of phosphorus, for example arsenic; and alternative p-type dopants may also be used instead of boron, for example gallium.

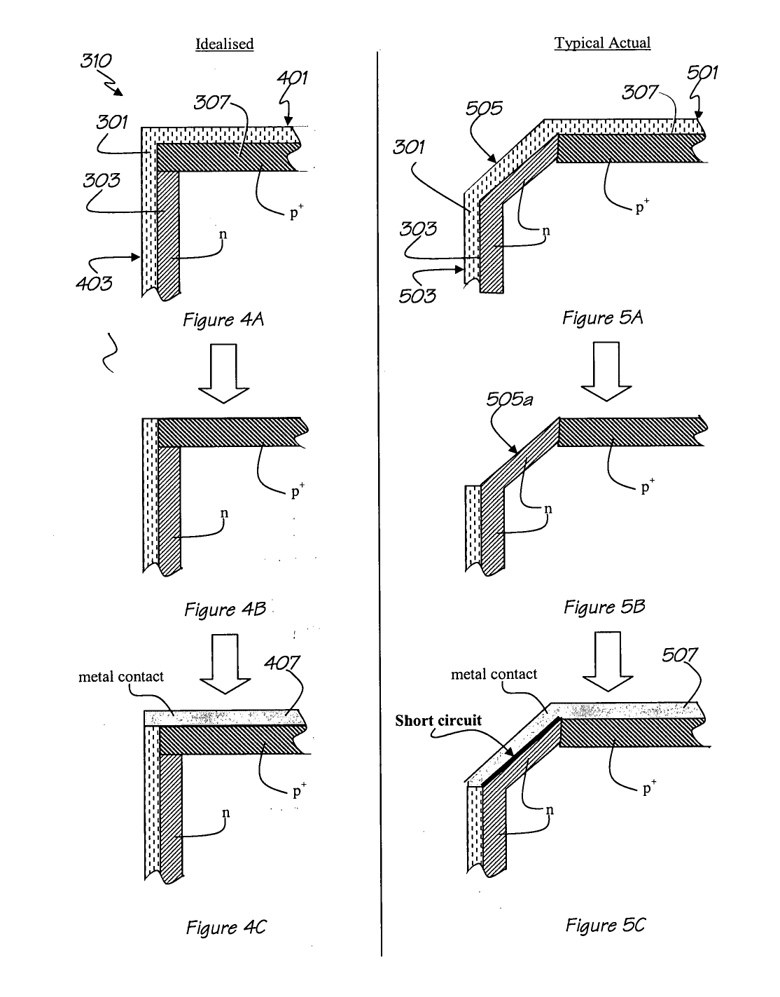

Starting with this structure, subsequent process steps remove the dielectric coating 301 to from the edges and deposit an electrically conductive material (usually a metal) onto the exposed highly doped edge surfaces in order to make good, low resistance electrical contacts to the cell. FIGS. 4A to 4C are schematic cross-sectional for an idealised elongate solar cell at different stages of its production which illustrate these steps, namely: FIG. 4A—just after formation of a dielectric coating; FIG. 4B—just after removal of the top-facing portion of the dielectric is coating; and FIG. 4C—after formation of an electrically conductive material (typically metal deposition) on the exposed surfaces of the solar cell FIGS. 4A to 4C show only the top-left corner of the cell of FIG. 3, as indicated by the dashed circles 310 in FIG. 3.

In a typical process, starting with the structure of FIG. 3, the edges 101 and faces 103 are coated with the dielectric 301. A corner detail 310 of the cell cross section is shown in FIG. 4A FIG. 4A for instructional purposes. A subtractive process (which may be a directional process, for example, reactive ion etching or plasma etching) is applied from the top 401 of FIG. 4A to remove the dielectric 301 from only the top-facing surfaces (i.e., the edges), whilst leaving the coating 301 on the faces 403, resulting in the structure shown in FIG. 4B. Next, a deposition process (which may be a directional process, for example, vacuum evaporation) is used to deposit the contact metal 407 as shown in FIG. 4C onto the exposed highly doped p-type edge, thus forming a good Ohmic contact to that edge.

However, FIGS. 4A to 4C shown an idealised structure wherein the edge 401 and face 403 are perfectly orthogonal and abut one another. In practice, and in particular where the elongate substrate from which the cell is formed is formed by anisotropic etching as described in the sliver patent application, as shown in FIG. 5A the edge 501 and face 503 of many elongate solar cells in a given wafer do not meet at a right angle along the entire intersection of the edge and face, but instead, some regions are joined by an intermediate surface 505 that is an artefact of the (imperfectly selective) etching process used to form the elongate semiconductor body of the cell. It has been found that, during typical practical manufacturing processes, if the same steps are repeated to remove the dielectric layer from the edge 501 then intermediate edge 505a exposes the n-type doping on the face 503. Depositing a metal contact 507 onto the edge, as is apparent from FIG. 5C, the initial intermediate surface 505 causes the p-type edge 501 and the n-type face 503 to become short-circuited by the overlaying metal contact layer 507 (compare the idealised structure of FIG. 4C where shorting does not occur). Moreover, a variety of different geometrical shapes can arise at such processing defects, and the particular processing defect illustrated in FIGS. 5A to 5C is only one example of these.

Because the orientation of the intermediate surface 505 is intermediate between the orthogonal orientations of the (vertical) face 503 and (horizontal) edge 501, highly directional additive and subtractive processes such as reactive ion etching, vacuum evaporation of metal, or laser processing that are intended to act only upon the horizontal surfaces (e.g. edge 501 as shown in FIGS. 4A to 4C) will also act upon the intermediate surface 505.

A consequence of this is that, when the dielectric is removed from the upwardly facing p-type edge surface 501, it is also removed from the n-type intermediate surface 505, as shown in FIG. 5B to expose the underlying n-type material (surface 505a). Similarly, when the contact metal 507 is deposited, it is deposited not only onto the exposed p-type surface of the edge, but also onto the exposed n-type intermediate surface 505a, as shown in FIG. 5C. It will be apparent that this results in the p-type edge and the n-type face becoming short-circuited by the overlaying metal layer 507 (compared with the idealised structure of FIG. 4C where shorting does not occur).

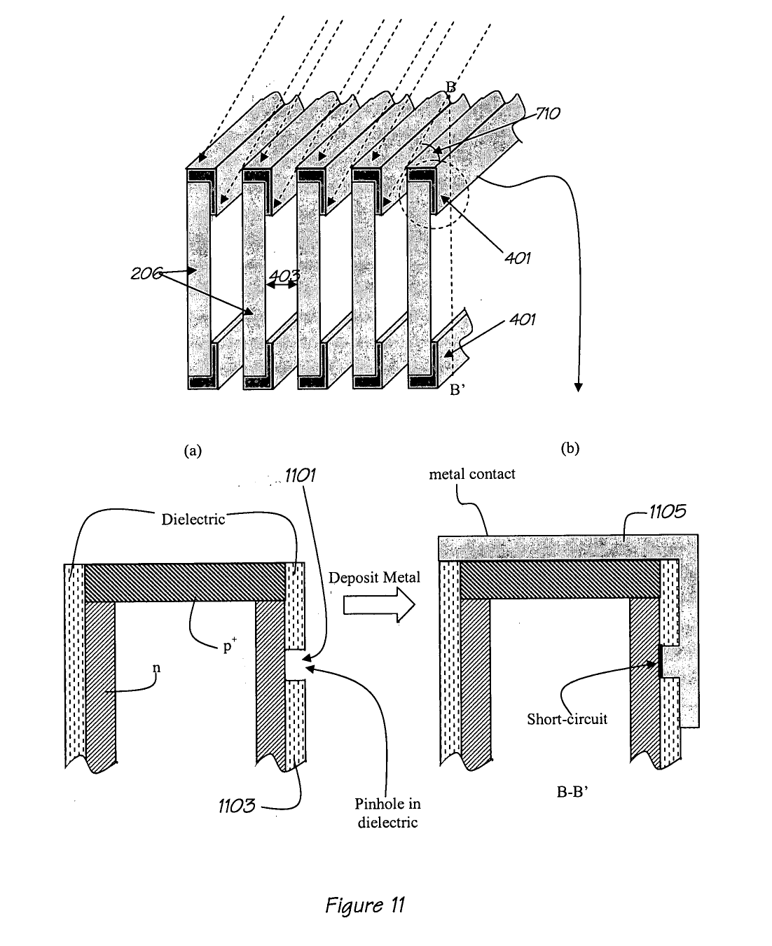

Additionally, pinholes in dielectric materials can form at any stage of the processing of a cell, and can cause a variety of problems, including doping unintended regions or electrical short circuits forming through the pinholes. This situation is depicted schematically in FIG. 11 (idealised) where the pinhole 1101 in the dielectric layer 1103 (a) causes a short circuit between the p-type edge and the n-type face when the metal contact layer 1005 is added (b). The use of discontinuous, mutually spaced doping regions, metallisations, openings, and dielectric regions as described herein reduce the probability of including a pinhole in doped or electrically contacted regions.

Therefore, cell structure and metallic contact designs must be considered with the aim of separating the metallic contacts from the doped semiconductor contact/junction layers. A selection of cell structure options (idealised) for counteracting the above shorting issues induced during process are depicted in FIG. 6A. Cell structures 610, 620, and 630 depict options whereby the metal contact (615, 625, & 635 respectively) to the doped emitter region (611, 621, & 631 respectively) is sufficiently separated from the doped base region (613, 623, & 633 respectively) such that shorting is unlikely to occur. In each of cell structure options 610, 620, and 630, the metal contact (615, 625, & 635 respectively) covers the entire edge of the elongate cells. There still may be concerns using these cell structures of shunting occurring during typical manufacturing processes as discussed above and/or due to other imperfections that are common in practice which may cause a shunt. For example, metal 635 in cell structure 630 may be extended further along the cell face, where possible pinholes described above will cause formation of a shunt. Generally by reducing the area coverage of the metal (i.e. by using a fractional contact) there is a chance to reduce the probability that these imperfections cause a shunt.

The aspects and arrangements of the elongate solar cells and manufacturing processing methods for obtaining these as described herein mitigate these and other forms of undesirable processing artefacts or processing defects that adversely affect the performance of elongate solar cells. This is achieved by forming the electrical contact to at least one of the edges of each cell so that it contacts only a fractional portion of the edge of the elongate substrate/solar cell, in some cases only a relatively small portion, thus reducing the impact of such defects and thereby improving the performance of the elongate solar cell.

In contrast, to the cell structures described above, cell structure options 640 (with active faces 644 and 644a) and 650 (with active faces 654 and 654a) depict the metallic base contact (645 & 655 respectively) contacting only a fraction (647 & 657 respectively) of the base region (641 & 651 respectively) on the edge (642 & 652 respectively) of the cell. The fraction of the base region contacted by the metallic contact may vary between 0.01% of the surface area of the edge of the cell to just less than 100% of the surface area (e.g. about 98-90%). In this and similar arrangements, the fractional portion of the edge which is contacted by the metal may be between about 1% and about 99% of the total surface area of the edge. For example, the metallic contact may contact with about 1%, 5%, 10%, 20%, 25%, 35%, 50%, 60%, 70%, 80%, 90% 95%, 98% or about 99% of the surface area of the edge. Cell structure 650 also has additional advantages since the base and emitter diffusion regions (651 and 653 respectively) are abutting which provides reverse breakdown protection for the cell.

Aspects and arrangements of the elongate solar cells are described herein in the context of elongate solar cells formed by anisotropic chemical etching of p-type silicon wafers having a thickness of 0.3-2 mm, although wafers with thickness in the range of about 0.1 to about 5 mm can also be used. However, it should be understood that the invention can also be applied to elongate solar cells made by other means, from other semiconductors, and/or doped using other dopant species and/or using different doping configurations to those described herein, which have been selected because they represent the most typical arrangements used today. For example, the n-type and p-type wafers and doped diffusion regions in the structures and example disclosed herein can be interchanged simply by replacing “p-type” with “n-type” and vice versa to obtain a solar cell with emitter area of the different polarities.

In a particular arrangement as depicted in FIG. 8, a fractional metallic contact to an edge 101 can be achieved by forming one or more openings 801 (also referred to as ‘windows’) is in the dielectric coating 803 (rather than removing the entire coating on the edge) of the slivers and then depositing the contact metal (not shown) onto the resulting structure so that the metal only contacts the edge 101 and the intermediate surface in those exposed regions 801.

In a further, an alignment technique such as photolithography can be used to confine electrical contact to the cell edges 101 entirely to the centre of each edge, so that the contact does not intersect with the face at all, the complementary region of the edges around the contact remaining coated with the dielectric. In this and similar arrangements, the fractional portion of the edge which is contacted by the metal may be less than 100% of the surface area of the edge, for example between about 0.01% and about 99% of the total surface area of the edge. For example, the metallic contact may contact with about 0.01%, 0.05%, 1%, 5%, 10%, 20%, 25%, 35%, 50%, 60%, 70%, 80%, 90% 95% 98% or about 99% of the surface area of the edge, where the edge surface area is the length, l, of the elongate cell multiplied by its thickness, t.

In addition, as depicted in cell structure 640 of FIG. 6B, the base doping region 641 on the edge 642 can be confined entirely to the centre of the edge 642, so that the edge-doping does not intersect with the doped emitter regions 643 on the cell faces 643 at all.

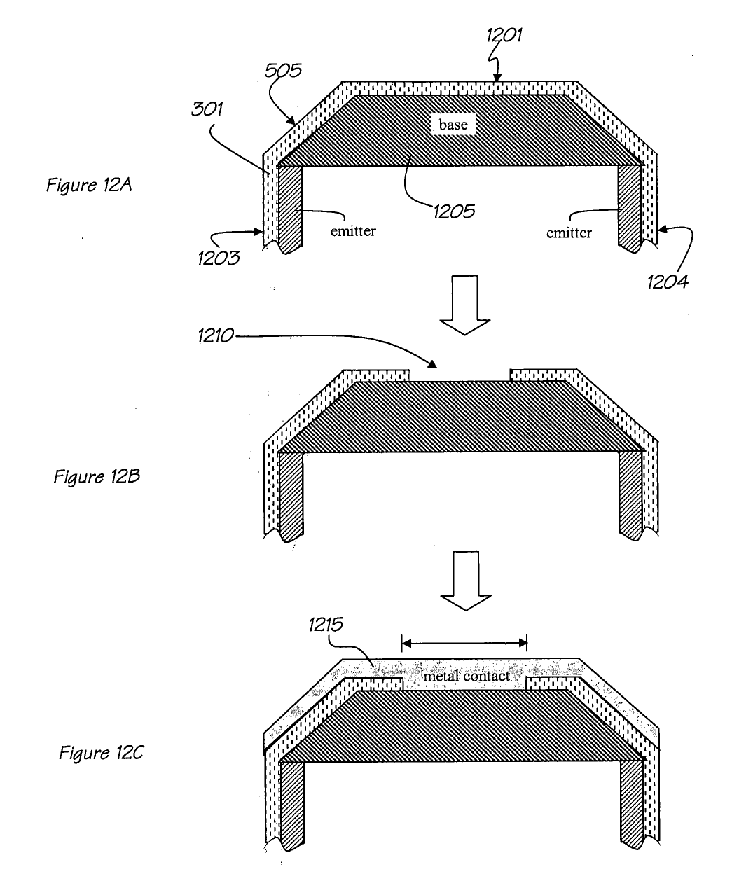

In a further arrangement, a process for fabricating the cell structures 650 of FIG. 6B is depicted in FIGS. 12A to 12C. A typical actual structure with imperfect corners between the edge 1201 and face 1203 (and also face 1204), similar to FIGS. 5A to 5C. As before, the cell is coated with a dielectric coating 301 on both the edges and the faces (FIG. 12A). In FIG. 12B a direction subtractive process has been used to remove a portion of the dielectric coating from the edge 1201 to create a void 1210 which exposes a fractional portion of the surface area of the doped base region 1205 on edge 1201. Next, a directional deposition process is used to deposit the metal contact material onto the edge 1201 of the cell, whereby the metal fills the void 1210 and therefore contacts the base region 1205 in only a fractional portion of the surface area of the edge 1201. As depicted in FIGS. 13A to 13C the fractional portion of the base region 1305 may be used to create metal contact area according to requirements, for example to just less than 100% of the surface area of the top surface of the cell (FIG. 13A), to about 50% of the surface area of the top surface top (FIG. 13B), or only a relatively small portion of the surface area of the top surface (FIG. 13C), or alternatively any fractional portion therebetween. Alternatively, multiple contact regions may be formed as depicted in FIGS. 13D and 13E showing two and three regions respectively where the metal contacts with the base region 1305 of the cell. In all cases, the fractional portion of the edge which is contacted by the metal may be less than 100% of the surface area of the edge, for example between about 0.01% and about 99% of the total surface area of the edge. For example, the metallic contact may contact with about 0.01%, 0.05%, 1%, 5%, 10%, 20%, 25%, 35%, 50%, 60%, 70%, 80%, 90% 95% 98% or about 99% of the surface area of the edge.

However, these arrangements also have some disadvantages. In particular, an alignment step is required to ensure that the openings in the insulating dielectric for the electrical contacts are midway between, and parallel to, the edges of each cell. Options for aligning and forming these openings are reduced if this step is performed after etching of the slots between the cells, because traditional techniques such as photolithography can no longer be readily used. Additionally, some type of processing defects are quite large, and can extend well into the edge region, and so the problem of defects may persist.

To alleviate these shortcomings, other embodiments reduce the effects of processing defects not so much by avoiding those regions of the edge located at or near the cell faces, but rather by reducing the total proportion of the edge surface to which contact is made, thereby correspondingly reducing the number of defects that are exposed to the electrical contacts. The regions of the edge surfaces not contacted remain coated by the dielectric to reduce their potential for deleterious effects.

Moreover, rather than contact each edge at a single (but long) contact region, in some embodiments each edge is contacted at a plurality of (shorter/smaller) contact regions in order to relax or avoid any need to precisely align the desired pattern of contact regions with the edges of the elongate substrates.

For example, in one embodiment, many small openings are formed in the dielectric on at least one of the edges of each elongate cell, so that the combined area of these openings comprises only a fractional portion of the total surface area of the edge. In this case, the process may be well suited where the fractional portion is only a small portion of the total surface area, for example less than about 30% to about 50%, of the total area of the edge. The fraction portion may be higher, i.e. greater than 50% to about 99%, with the trade of the yield of cells without defects will be lower. For example, where the fractional portion is about 10% of the total surface area of the edge, the expected reduction of the reject rate of cells due to specific defects will be ×10. Similarly, where the fractional portion is about 90% of the total surface area of the edge, the expected reduction of the reject rate of cells due to specific defects will be only about 10%, that is, the reduction of the overall exposure to defects will be lower as the fractional portion of the edge contacted increases. Subsequently, a metal is deposited over the dielectric and the openings so that the metal contacts the doped silicon only in the regions exposed by the openings, thereby reducing the overall exposure of the electrical contact to processing defects by about a factor dependent on the fraction of the surface area exposed by the openings (e.g. where the total exposed surface area is only about 10%, this process would reduce the overall exposure of the electrical contact by a factor of ten, assuming the openings are uniformly distributed).

Such contacts to only a relatively small portion (e.g. less than about 10%) of each edge are nevertheless still sufficient to provide reliable low resistance electrical contacts, provided that the doping concentration in the contacted semiconductor regions is high enough to sufficiently reduce contact resistance losses. This is easily achieved by doping the relevant regions of the edges heavily to achieve a sufficient surface doping concentrations, according to well-established standard semiconductor process protocols, which differ for contacts to n and p type regions. Typical boron (p-type) and phosphorus (n-type) surface doping density is in the range 10¹⁸-10²¹ cm⁻³. Alternatively, heterojunction contacts can be formed. Heterojunctions are well known methods of contacting a semiconductor, and include a different semiconductor material than the semiconductor substrate, whereby the two semiconductors have different work functions. Typically, a heterojunction contact will be fabricated from a wider bandgap semiconductor. An example that has been used for silicon solar cells comprise crystalline and amorphous silicon material.

The openings in the dielectric coating can have essentially any shape, but are preferably in the form of small dots or lines. In the latter case, if the lines are inclined relative to the longitudinal axis of each edge, then they will occupy a known proportion of the cell edge that depends only upon the width and pitch of the lines. The spacing of the dots or lines can be selected by performing standard electrical resistance calculations in order to avoid excessive series resistance associated with the transport of electrons and holes to the electrical contacts.

### Patterning

Various methods can be used to create diffused and metallised patterns of openings (windows) in insulating or dielectric layers or coatings. It is straightforward to use photolithography prior to the etching of slots through the wafer. However, once the slots have been formed, the resulting topography inhibits the use of conventional photolithography.

A laser or a mechanical scribing process can also be used to create patterns. In is principle, these methods can be successfully used at any stage in the process sequence because they can cope with rugged topography.

Some patterning methods, such as photolithography, reactive ion etching, etching pastes or the use of ultrafast UV lasers, can remove dielectric layers with minimal damage to the underlying silicon. This has the advantage that removal of the dielectric layer can be accomplished without damage to the underlying silicon or the removal of diffusion layers near the surface of the silicon. Other patterning methods in addition to those described above are also possible and may be useful.

However, it is advantageous to reduce process complexity and cost, for example by reducing or eliminating the use of photolithography, where possible. In particular, photolithographic alignment of a pattern to an existing pattern requires relatively sophisticated and expensive technology. The cost of precise alignment can be significant, regardless of whether photolithography or some other patterning technique is used.

### Reduced Area/Fractional Contacts

It is not necessary to make openings in the dielectric layer prior to metal deposition in order to make electrical contacts through it. In a particular arrangement, a contact metal is deposited over the dielectric layer without any openings having been formed in the dielectric coating. Subsequently, a laser beam is used to locally heat the contact metal in selected region(s) (e.g. at a plurality of mutually spaced locations) to drive the metal through the dielectric in those region(s), and thereby make electrical contact to the underlying silicon only at those region(s).

In another arrangement, the contact metal is deposited only at mutually spaced location(s) on the dielectric layer (e.g., in the form of dots or stripes), and driven through the dielectric layer by heating the whole wafer, thereby making electrical contact to the silicon underlying the region(s) of deposited metal. These dots or stripes of metal are then electrically interconnected by depositing an additional layer of metal that electrically connects the previously deposited metal regions together.

### Reduced Area Diffusions

In the arrangements described above, the entire surface of each edge is relatively highly doped to enable Ohmic electrical contact to the cell to be formed, even though electrical contact is directly made only to a fractional portion of the edge surface. In otherarrangements, the edge surface is highly doped only in localised regions corresponding to the regions where the contact metal directly contacts the semiconductor. This provides several advantages.

Firstly, minority carrier recombination losses associated with the highly doped regions are reduced. Although heavy doping (usually with phosphorus or boron dopants, as appropriate, if the semiconductor is silicon) of the semiconductor surface layer to be contacted reduces zo electrical contact resistance losses and suppresses minority carrier recombination at the metal-semiconductor interface, the high concentration of dopant atoms in the doped bulk regions below the surface increases minority carrier recombination. Consequently, by reducing the volume of highly doped semiconductor, the minority carrier lifetime and hence the efficiency of the cell are correspondingly increased.

Secondly, the perimeter length over which doped p-type and doped n-type regions abut is also correspondingly reduced. Doped emitter and base regions of opposite polarity that abut are associated with increased recombination rates in the compensated region that forms at the intersection which provides reverse breakdown protection for the cell. In addition, electrical short-circuiting by carrier tunnelling is possible. These problems are exacerbated when the doping concentrations of the abutting regions are both high. Although this problem can be managed by careful adjustment of doping concentrations (for example, by driving-in dopants at high temperature to reduce peak dopant concentrations), such management can be difficult and/or inconvenient. Consequently, the reduction in the length of the perimeter between diffused regions of opposite polarity mitigates these difficulties.

Additionally, the reduction of highly doped regions reduces the probability of forming inadvertent electrical shunt paths. For example, the reduction in the area of heavily doped regions reduces the probability of inadvertent diffusion of dopant atoms through processing defects such as pinholes in a masking dielectric layer. The creation of such inadvertently doped regions (for example, within the boundaries of an oppositely doped region) can lead to electrical short circuits.

In another arrangement, localised doping and metal contact are achieved in a single processing step by incorporating dopant atoms within the contact metal and then either locally heating the metal to drive it through the dielectric, as described above, or locally depositing the metal and heating it, as described above.

Reducing or Eliminating Intersection of Diffused Regions with Slot Edges During Etching

Finally, the reduction in the volume of highly doped semiconductor at and near the edge can also be achieved by patterning the doped regions in a manner that improves the quality of the elongate substrates formed by anisotropic etching.

When many elongate substrates are formed from a single wafer by anisotropic etching, the substrate edges, which are co-planar with the wafer surface, are usually heavily doped by doping (oppositely) the entirety of both wafer surfaces prior to the anisotropic etching step. However, the resulting surface doping can interfere with the anisotropic etching by changing the etch rates at one or both wafer surfaces. For example, in the case of silicon, phosphorus and boron doping changes the etch rate in a variety of etching solutions. Heavy boron doping generally reduces etch rates in anisotropic etch solutions, whereas heavy phosphorus doping can accelerate etch rates, potentially causing undesirable lateral etching at the n-type wafer surface, leading to widening of the etch slots. Indeed, heavy diffusion of dopants of either polarity into the wafer surfaces can create defects in the silicon that lead to accelerated lateral etching. Additionally, the adhesion of masking layers that nominally resist etching by the silicon etching solution may be compromised by heavy boron and phosphorus diffusions.

Consequently, heavy diffusions, particularly those that intersect the edge of the etched slots, can complicate slot formation by etching. If very narrow slots are to be created, then this is particularly problematical.

In a particular arrangement, heavily doped surface regions of one or both polarities are formed prior to etching by dopant diffusion through a patterned mask in order to form mutually spaced doped surface regions that are also spaced from the wafer surface regions corresponding to the slots subsequently formed by etching. FIG. 10, depicts is a schematic diagram showing perspective and plan views of an edge of an elongate semiconductor body. Selectively doped surface regions along the edge 1001 can be achieved by confining the doped region to one (e.g. plan view 1010) or more (e.g. two stripes in plan view 1020) narrow stripes down what will become the centre line of the elongate substrates. The edge 1001 is selectively doped along an elongate region centrally disposed along the longitudinal axis of the edge and spaced from the two faces of the semiconductor body that intersect the edge. This selective doping reducing the probability of the doped regions abutting or intersecting the doped surface regions of the two faces. this Because the diffused regions are narrower than the edges of the elongate substrates, then the diffused regions will not intersect with or overlap the slots formed by etching. However, this embodiment requires an aligned patterning step to ensure that the diffused regions and the slots do not overlap, intersect or abut in any way.

In other arrangements, this difficulty is overcome by patterning the dielectric for masked doping to form doped surface regions in the shape of parallel stripes that are inclined at a substantial angle to the longitudinal axes of the elongate substrates. If the stripes are relatively narrow compared with their spacing (pitch), then the length of intersection between the diffused regions and the slots is controllable and relatively small. The extent of difficulties arising during slot etching caused by the intersection of diffused regions and the slots is reduced in proportion to the reduction in length. A particular advantage of these embodiments is that the problem can be reduced without needing to align the patterned windows in the dielectric with the slots.

Delaying Heavy Phosphorus and/or Boron Diffusions Until after Slot Formation

As an alternative to the arrangements discussed above, diffusions of one or both dopant polarities into respective edges of each elongate substrate can be performed after slot etching. This reduces or eliminates the problems described above and arising from the overlap, intersection or abutment of diffused regions with the slots subsequently formed by etching.

In general, the selective doping of the elongate substrate edges after the substrates have been formed can be accomplished by selectively removing the dielectric layer only from the substrate edges (using a directional etching technique such as reactive ion etching that can be used to preferentially etch regions that are substantially parallel to the surface of the wafer) and then doping the exposed edges of the silicon (typically by furnace diffusion). If the silicon is coated with multiple layers, then a combination of methods can be used. For example, where the silicon is coated with silicon dioxide layer and a silicon nitride layer, reactive ion etching can be used to remove the overlying silicon nitride layer, and then (isotropic) wet etching used to remove the underlying silicon dioxide layer.

In some arrangements, mutually spaced regions of at least one of the edges of each substrate are selectively doped after the substrates have been formed. In some embodiments, this is accomplished by selective removal of corresponding mutually spaced regions of a masking dielectric layer using a laser, mechanical scriber, or selective application of an etch paste, followed by a dopant diffusion step.

In some arrangements, one or more selected portions of each edge are doped by forming corresponding openings in the dielectric masking layer, where the openings are in the form of elongate stripes that run along the centre line of each edge. Each edge can have a single opening, or multiple openings. In one embodiment, a directed laser is used to form each opening in the dielectric layer. However, these embodiments have the disadvantage that they require alignment of the openings with the substrate edges. Where the openings are formed after the elongate substrates have been formed, such alignment can be difficult because the substrates, particularly if they are very thin, sometimes do not remain parallel but rather become curved, thus making alignment difficult and in some cases impractical.

In one particular arrangement, the need to precisely align the openings is relaxed or avoided by forming the openings in the dielectric coating as an array of parallel stripes inclined at a substantial angle to the longitudinal axes of elongate substrates; in another the openings are in the form of a regular or random array of spots or other non-elongate shape, thus avoid the need for precise alignment of the openings with the elongate substrates. This is a major advantage if each substrate is not perfectly positioned and straight, as is often the case in practice.

In further arrangements, the introduction of dopant atoms into the substrate edges after slot etching is achieved using a liquid-jet-guided laser beam in conjunction with a jet-liquid containing the desired dopant atoms, using a liquid-guided laser system based on a Laser MicroJet™ system manufactured by Synova SA, as described at http://www.synova.ch. For example, where n-type doping of silicon is desired, phosphoric acid can be used as the laser guiding liquid. This is particularly advantageous because the doping is performed at a relatively low temperature, and in a manner that does not require masking of other areas of the cell to avoid inadvertent diffusion into unintended regions. Application of this doping technology to elongate cells, as described herein, allows discontinuous edge doping of mutually spaced doped regions to be directly and easily formed.

In one particular arrangement, a liquid-jet-guided laser beam is used to locally form one or more openings in a dielectric coating and optionally also to simultaneously dope one or more corresponding regions of the semiconductor body. For example, a liquid-jet-guided laser forms a shallow (e.g., about 10-15 μm) trench in the semiconductor while at the same time disrupting an overlying dielectric coating (typically a silicon nitride layer). If the liquid jet contains a dopant species, then the walls of the trench are simultaneously doped in the same process step. One or more electrical contacts to the semiconductor body can then be formed by depositing an electrically conductive material, either locally at each opening, or more broadly to cover not only the openings, but also the remaining dielectric coating. In either case, the electrically conductive material only contacts those regions of the semiconductor body that are exposed by the openings formed by the liquid-jet-guided laser beam.

In an alternative arrangement, one or more localised regions of the semiconductor body are selectively doped by laser doping, but without requiring a liquid-jet-guided laser beam. In this embodiment, a layer of doping material containing a dopant species (e.g., phosphorus oxide glass) is deposited over the semiconductor body, and is subsequently locally heated with a laser beam to drive the dopant species into corresponding regions of the semiconductor body. The layer of material containing the dopant species can contact the semiconductor body directly, or alternatively can be separated from the semiconductor body by a layer of dielectric material. In the latter case, the laser beam is strongly absorbed in the underlying semiconductor and the resulting heating disrupts the dielectric coating to allow the dopant species to be driven into the exposed surface(s) of the semiconductor body. As with the arrangements described above, one or more electrical contacts to the semiconductor body are then formed by depositing an electrically conductive material, either locally, or more broadly. In either case, the electrically conductive material only contacts those regions of the semiconductor body that are exposed by the openings formed by the laser beam.

### Thermal Treatments

Although the processes described above reduce the impact of processing defects on the performance of elongate solar cells, particularly those formed by anisotropic etching, thermal treatments can be used in conjunction with those processes to further improve solar cell performance.

It is well known that intersecting regions that are heavily doped with opposite polarity doping can have electrical short circuits appearing between the two regions due to electron tunneling. Devices such as the tunnel diode take advantage of this phenomenon. In a solar cell, such a short circuit will generally reduce performance, and is usually best avoided. Adjacent heavy diffusions of opposite polarity into the silicon surface can give rise to such difficulties if they intersect, for example at the boundary between an edge and a face in an elongate solar cell. Thermal treatments can be used to lower the concentration of dopants in one or both of the doped regions where they are highest, which is generally at or near the surface. However, such thermal treatments are problematical in this example, because two problems should be simultaneously addressed: the need to avoid short circuits between intersecting heavily doped regions, and the need to ensure that one doping type predominates across the entire surface of the edge. Careful adjustment of both the doping dose/fluence and the subsequent thermal history can avoid both of these problems. For example, in the case of an elongate cell with phosphorus diffused faces and one boron diffused edge, where the sheet resistance of the two diffusions after drive in is in the vicinity of 100 Ohms per square and 40 Ohms per square, respectively, a drive-in heating step at 1100 degrees C. for 60 minutes eliminates short circuits whilst preserving boron as the dominant impurity across the whole of the edge of the cell.

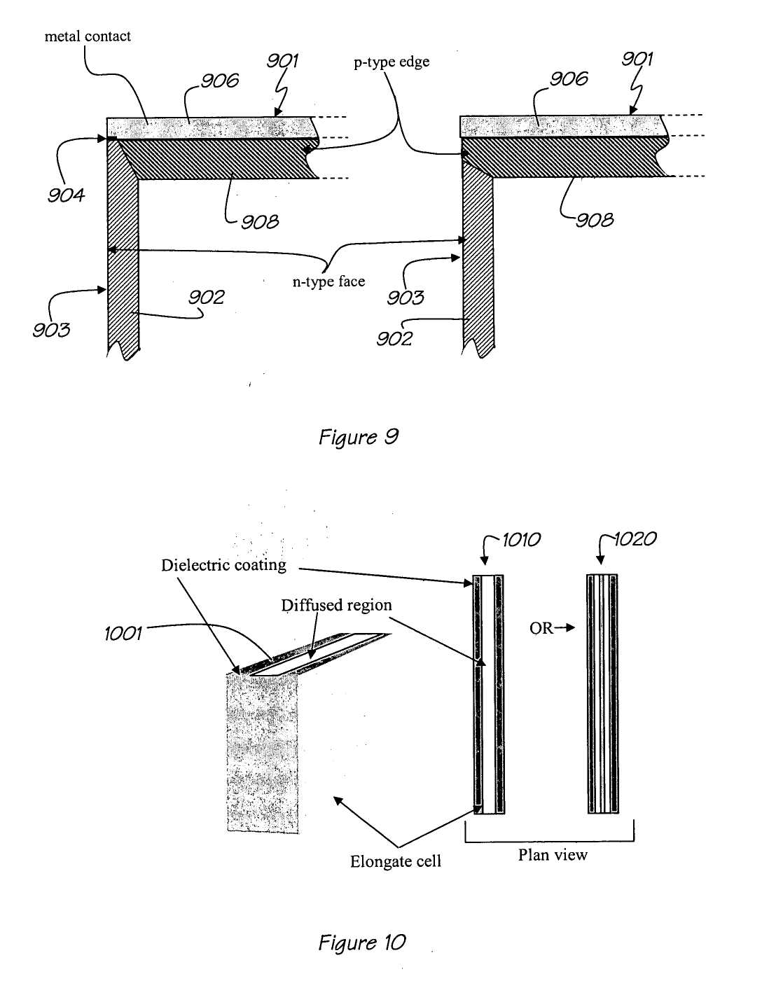

The left-hand side of FIG. 9 is a schematic view of a face 901 and edge 903 of an elongate solar cell at one stage during its production, showing how the n-type (or alternatively, p-type) face doping 902 extends to the surface of the p-type (or alternatively, n-type) edge 901 at one region 904, causing a short circuit to appear between n and p type regions 902 and 908 after formation of the metallisation contact layer 906. The right-hand side of FIG. 9 shows the effect of the thermal treatment described above, which causes the heavier boron p-type doping 908 on the edge 901 to diffuse into the short-circuit region 904, thereby dominating across the entire surface of the edge 901 and, counter-doping the initially n-type region 902 near the edge 901 so that the entire surface of the edge 901 becomes p-type, thereby avoiding a short circuit.

For conventional elongate solar cell designs, processing defects will have a less severe effect if they are at an edge of the opposite doping polarity to the background doping of the semiconductor body of the cell. The reason for this is that the faces are also doped oppositely to the substrate of the cell, and so shorting the face to the edge does not cause a short circuit in the solar cell because the face and edge have the same doping polarity.

### EXAMPLES

### Example 1

In a first example a plurality of elongate solar cells held in a frame of a semiconductor wafer, each cell having fractional edge contacts, was formed using the following process.

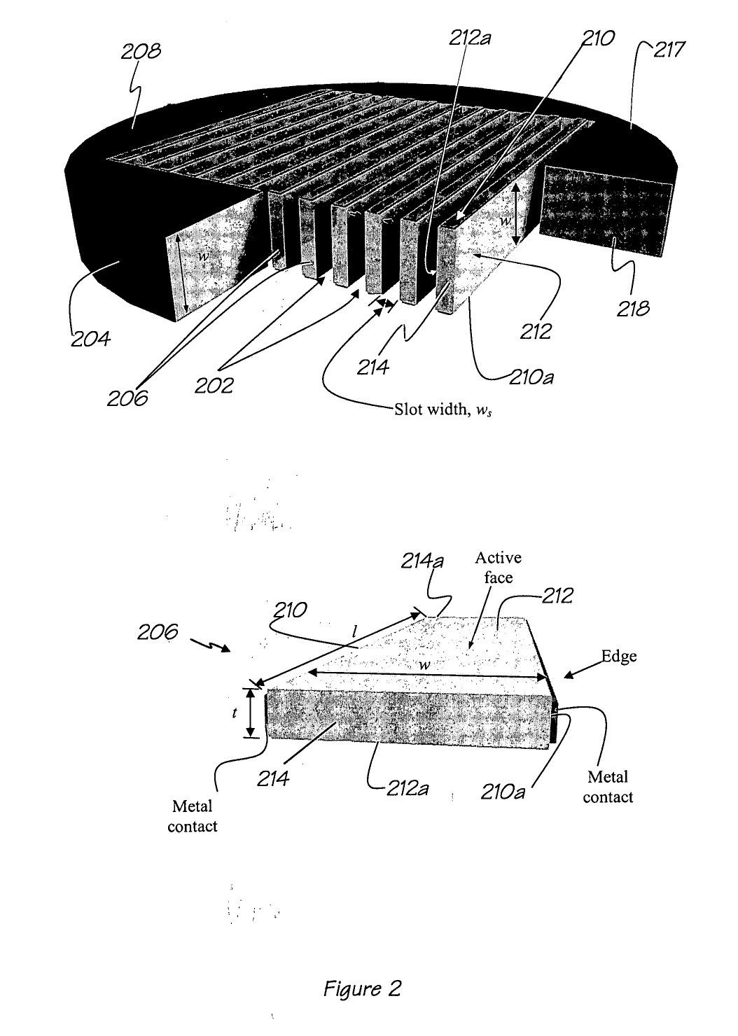

An n-type dopant (e.g. phosphorus or arsenic) was initially diffused into one surface (e.g. the top surface, corresponding to one edge of the cell after formation of the elongate cells) of a p-type (110) oriented 1 mm thick silicon wafer to achieve sheet resistance (Rₛ) in the range is of about 20 to about 350Ω/□ (Ohms-per-square) and a p-type dopant (e.g. boron or gallium) diffused into the reverse surface to achieve sheet resistance, Rₛ, in the range of between about 20 to about 80Ω/□ (i.e. heavily doped), taking steps to avoid cross-doping. After further processing (to form slots in the wafer and form the elongate substrates of FIG. 2), these surfaces will become the edges of the elongate solar cells. Alternative wafer thicknesses may also be used, where the thickness of the wafer may be selected between about 0.2 mm and about 5 mm. As would be appreciated by the skilled addressee, the dopant types may be reversed mutandis mutandi by replacing “n-type” with “p-type” and vice versa.

A protective dielectric coating was applied to the top and bottom surfaces of the wafer, and elongate windows in this coating were opened using lithography (e.g. photolithography) and reactive ion etching operations. A plurality of deep and narrow trenches were etched through the entire wafer in the region of the elongate windows to form the plurality of elongate substrates held within a frame as depicted in FIG. 2. The sidewalls of these trenches become the faces of the elongate solar cells. Alternatively, the trenches may be formed nearly through the wafer, for example greater than 95% of the wafer thickness or to within about 50 μm or less of the rear surface of the wafer. The small portion of remaining wafer at the bottom of the trench may assist in maintaining the separation of the elongate substrates during subsequent processing steps.

The wafer was next diffused with a n-type dopant (e.g. phosphorous or arsenic) using a gas phase deposition process. A suitable dopant source for phosphorous diffusion is POCl₃. All dielectric layers were removed in an acid solution (e.g. HF) and then the wafer was oxidised in an oxygen atmosphere at 1000° C. to form silicon dioxide.

A regularly spaced array of elongate contact openings if formed in the silicon dioxide coatings on both edges of the elongate cells (i.e. in the plane of the top and bottom surfaces of the wafer). The elongate contact openings are formed orthogonal to the longitudinal axis of each elongate substrate (cell), with a selected pitch (for example, about 0.5 to about 10 mm), such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%. A perspective and plan view of the orthogonal is openings in the dielectric material to expose the fractional portion of the edges is depicted in FIG. 8.

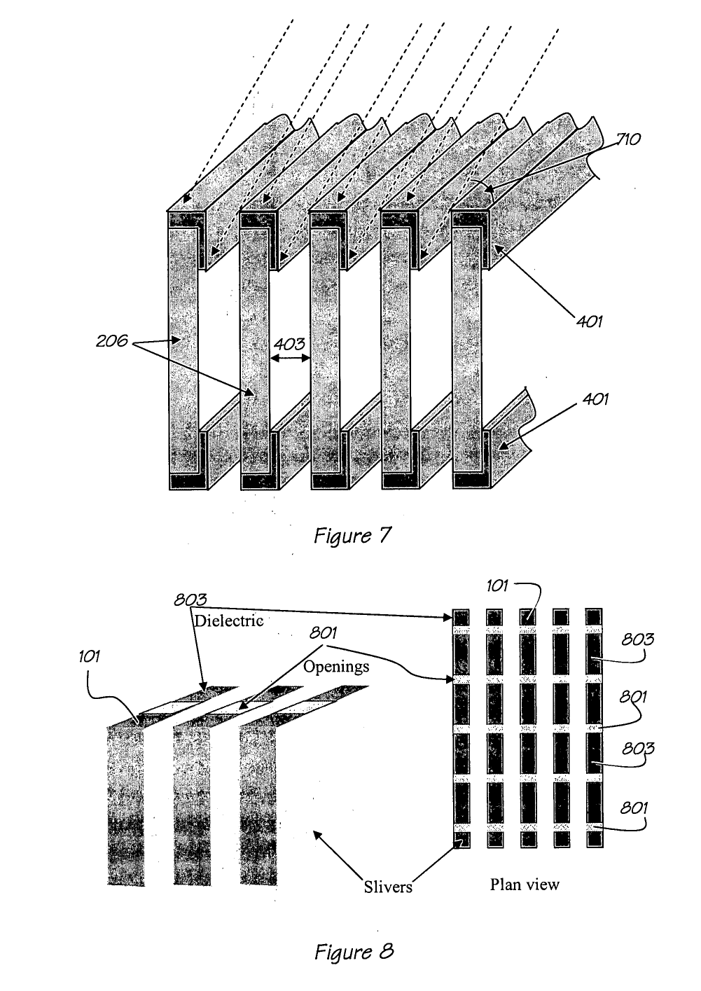

A metal is then evaporated onto each edge to form a fractional contact to the elongate solar cell. This metal will make intermittent contact to the openings in the dielectric layer on the slot edges. Examples of metals that may be used in this and in the subsequent examples for evaporation onto each edge include Co, Ni, Pd, Pt, Ti, Ag, Al and others. The metal structure may also contain a combination of those. The probability of a defect being present within these openings (which could cause a short circuit between n and p regions) is reduced by about a factor proportionate to the surface area of the edge contacted by the metal. The metal may be evaporated at an inclined angle 710 with respect to the faces, for example about 45° as depicted in FIG. 7.

The plurality of elongate solar cells held in the frame of the semiconductor wafer may then be separated from the wafer frame in further processing to form a plurality of individual separated elongate solar cells, each elongate solar cell having fractional edge contacts.

### Example 2

In a second example, a plurality of elongate solar cells held in a frame of a semiconductor wafer, each cell having fractional edge contacts, was formed using the following process.

An n-type dopant (e.g. phosphorus or arsenic) is diffused into one surface (e.g. the top surface, corresponding to one edge of the cell after formation of the elongate cells) of a p-type (110) oriented 1 mm thick silicon wafer to achieve a sheet resistance of about Rₛ≈20 to about 350Ω/□. Alternative wafer thicknesses may also be used, where the thickness of the wafer may be selected between about 0.2 mm and about 5 mm. As would be appreciated by the skilled addressee, the dopant types may be reversed mutandis mutandi by replacing “n-type” with “p-type” and vice versa.

A protective dielectric coating is deposited onto the surfaces of the wafer and elongate windows opened in this coating using lithography (e.g. photolithography) and reactive ion etching operations. A plurality of deep and narrow trenches were etched through the entire wafer in the regions of the elongate windows to form a plurality of elongate substrates held within a frame as depicted in FIG. 2. The sidewalls of these trenches become the faces of the elongate solar cells. Alternatively, the trenches may be formed nearly through the wafer, for example greater than 95% of the wafer thickness or to within about 50 μm or less of the rear surface of the wafer. The small portion of remaining wafer at the bottom of the trench may assist in maintaining the separation of the elongate substrates during subsequent processing steps.

An n-type dopant (e.g. phosphorus or arsenic) is diffused into both sidewalls of the trenches to achieve sheet resistance Rₛ in the range of between about 40Ω/□ and about 200Ω/□, therefore providing doping on the faces of the elongate substrates. A passivating oxide is grown on the faces and the n-type dopant is driven in at a high temperature in order to adjust the doping profiles of the diffused regions on the top surface of the wafer and on the faces of the elongate substrates. Next, a diffusion barrier material, such as silicon nitride, is formed on the faces of the elongate substrates.

Next, a regularly spaced array of openings in the dielectric coatings on the undoped edge of the elongate solar cells (the edge in the plane of the wafer that was undoped i.e. the bottom wafer surface), orthogonal to the longitudinal axis of each elongate solar cell (similar to that depicted in FIG. 8), with a selected pitch (for example, about 0.5 to about 10 mm) such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%.

A p-type dopant (e.g. boron or gallium) is next diffused into this array of openings using a gas phase diffusion process. A suitable dopant source for boron doping is BBr₃. The boron silicate glass formed during the diffusion process is removed afterwards in an acid solution (e.g. HF).

Next, a regularly spaced array of openings is created in the dielectric coatings on the n-type (phosphorus) doped edge (in the plane of the top surface of the wafer) of the elongate solar cells, orthogonal to the longitudinal axis of each elongate solar cell, with a selected pitch (for example, about 0.5 to about 10 mm), such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%.

A metal is then evaporated onto each edge to form a fractional contact to the elongate solar cell. This metal will make intermittent contact to the openings in the dielectric layer on the slot edges. The metal may be evaporated at an angle 710 with respect to the faces, for example 45° as depicted in FIG. 7.

The plurality of elongate solar cells held in the frame of the semiconductor wafer may then be separated from the wafer frame in further processing to form a plurality of individual separated elongate solar cells, each elongate solar cell having fractional edge contacts.

### Example 3

In a third example, a plurality of elongate solar cells held in a frame of a semiconductor wafer, each cell having fractional edge contacts, was formed using the following process.

A p-type dopant (e.g. boron or gallium) is diffused into one surface (e.g. the top surface) of a p-type (110) oriented 1 mm thick silicon wafer to achieve sheet resistance, Rₛ, in the range of about 20 to about 80Ω/□ (i.e. heavily doped). Alternative wafer thicknesses may also be used, where the thickness of the wafer may be selected between about 0.2 mm and about 5 mm. As would be appreciated by the skilled addressee, the dopant types may be reversed mutandis mutandi by replacing “n-type” with “p-type” and vice versa.

A protective dielectric coating is deposited onto the surfaces of the wafer and elongate windows opened in this coating using lithography and reactive ion etching operations, and a plurality of deep and narrow trenches etched through the entire wafer in the regions of the elongate windows to form a plurality of elongate substrates held within a frame as depicted in FIG. 2. The sidewalls of these trenches become the faces of the elongate solar cells. Alternatively, the trenches may be formed nearly through the wafer, for example greater than 95% of the wafer thickness or to within about 50 μm or less of the rear surface of the wafer. The small portion of remaining wafer at the bottom of the trench may assist in maintaining the separation of the elongate substrates during subsequent processing steps.

A n-type dopant (e.g. phosphorous or arsenic) is diffused into both sidewalls of the trenches to achieve sheet resistance Rₛ in the range of between about 40Ω/□ and about 200Ω/□, therefore providing doping on the faces of the elongate substrates. A passivating oxide is grown on the faces and the n-type dopant (phosphorus) is driven in at a high temperature in order to adjust the doping profiles of the diffused regions on the top surface of the wafer and on the faces of the elongate substrates.

Next, a surface electrical passivation material, such as silicon dioxide, is formed on the faces of the elongate substrates.

Using a liquid jet guided laser in combination with phosphoric acid, a regularly spaced array of openings is formed in the dielectric coatings and the surface region of the silicon on the hitherto undoped edge (i.e. in the plane of the bottom surface of the wafer) of the elongate solar cells, orthogonal to the long axis of each elongate solar cell (similar to that depicted in FIG. 8), with a selected pitch (for example, about 0.5 to about 10 mm), such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%. The diffusion glass is then removed from the openings.

Next, a regularly spaced array of openings is created in the dielectric coatings on the p-type (boron) doped edge (in the plane of the top surface of the wafer) of the elongate solar cells, orthogonal to the longitudinal axis of each elongate solar cell, with a pitch of selected pitch (for example, about 0.5 to 10 mm), such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%.

A metal is then evaporated onto each edge to form a fractional contact to the elongate solar cell. This metal will make intermittent contact to the openings in the dielectric layer on the slot edges. The metal may be evaporated at an angle 710 with respect to the faces, for example 45° as depicted in FIG. 7.

The plurality of elongate solar cells held in the frame of the semiconductor wafer may then be separated from the wafer frame in further processing to form a plurality of individual separated elongate solar cells, each elongate solar cell having fractional edge contacts.

### Example 4

In a fourth example, a plurality of elongate solar cells held in a frame of a semiconductor wafer, each cell having fractional edge contacts, was formed using the following process.

A p-type dopant is diffused into one surface (e.g. the top surface) of an n-type (110) oriented 1 mm thick silicon wafer. Alternative wafer thicknesses may also be used, where the thickness of the wafer may be selected between about 0.2 mm and about 5 mm. As would be appreciated by the skilled addressee, the dopant types may be reversed mutandis mutandi by replacing “n-type” with “p-type” and vice versa.

A protective dielectric coating is deposited onto the surfaces of the wafer and elongate windows opened in this coating using lithography and reactive ion etching operations, and a plurality of deep and narrow trenches etched through the entire wafer in the regions of the elongate windows to form a plurality of elongate substrates held within a frame as depicted in FIG. 2. The sidewalls of these trenches become the faces of the elongate solar cells. Alternatively, the trenches may be formed nearly through the wafer, for example greater than 95% of the wafer thickness or to within about 50 μm or less of the rear surface of the wafer. The small portion of remaining wafer at the bottom of the trench may assist in maintaining the separation of the elongate substrates during subsequent processing steps.

A p-type dopant is diffused into both sidewalls of the trenches to achieve sheet resistance Rₛ in the range of between about 40Ω/□ and about 200Ω/□, therefore providing doping on the faces of the elongate substrates. A passivating oxide is grown on the faces and the p-type dopant is driven in at a high temperature in order to adjust the doping profiles of the diffused regions on the top surface of the wafer and on the faces of the elongate substrates.

Next, a surface electrical passivation material, such as silicon dioxide, is formed on the faces of the elongate substrates.

Using a liquid jet guided laser in combination with phosphoric acid, one or more openings are formed in the dielectric coating on the edge of the elongate substrates in the plane of the wafer surfaces, perpendicular to the long axis of each elongate substrate (similar to that depicted in FIG. 8), such that the openings expose a fraction of the surface area of the top and bottom edges of the elongate substrates. The fraction of the surface area of each substrate that is exposed may be selected between about 0.01% and about 99% of the total surface area of the edges, e.g. about 1%, 10%, 25%, 50%, 75%, 90% 95%, 98% or about 99%. The diffusion glass is then removed from the openings.

A metal is then evaporated onto each edge to form a fractional contact to the elongate solar cell. The metal may be evaporated at an angle 710 with respect to the faces, for example 45° as depicted in FIG. 7.

The plurality of elongate solar cells held in the frame of the semiconductor wafer may then be separated from the wafer frame in further processing to form a plurality of individual separated elongate solar cells, each elongate solar cell having fractional edge contacts.

### Example 5

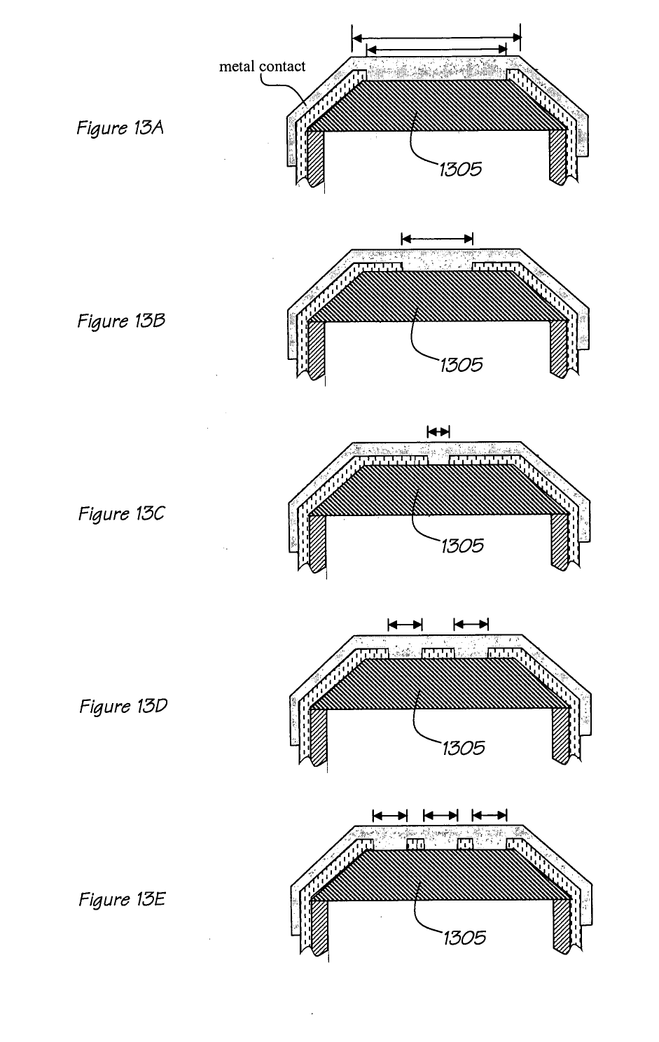

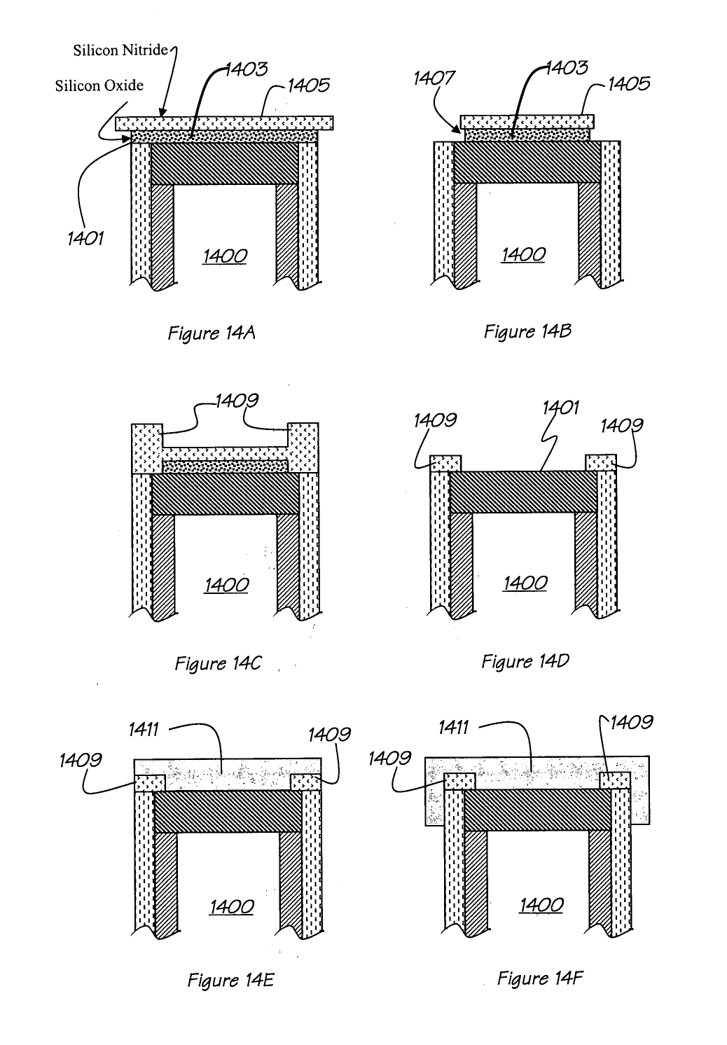

In a fifth example a plurality of elongate solar cells held in a frame of a semiconductor wafer, each cell having fractional edge contacts, was formed using the following process as depicted in FIGS. 14A to 14F.

An n-type dopant (e.g. phosphorus) was initially diffused into one surface of a p-type (110) oriented 1 mm thick silicon wafer to achieve sheet resistance (Rₛ) in the range of between about 20 to about 350Ω/□ (Ohms-per-square) and a p-type dopant (e.g. boron) diffused into the reverse surface with Rₛ in the range of about 20Ω/□ to about 80Ω/□ (i.e. heavily doped), taking steps to avoid cross-doping. Alternative wafer thicknesses may also be used, where the thickness of the wafer may be selected between about 0.2 mm and about 5 mm. As would be appreciated by the skilled addressee, the dopant types may be reversed mutandis mutandi by replacing “n-type” with “p-type” and vice versa.

A protective dielectric coating is deposited onto the surfaces of the wafer consisted of silicon dioxide (1403) and silicon nitride (1405) as depicted in FIG. 14 and elongate windows opened in this coating using photolithography and reactive ion etching operations. A plurality of deep and narrow trenches are then etched through the entire wafer in the regions of the elongate windows to form a plurality of elongate substrates held within a frame as depicted in FIG. 2. The sidewalls of these trenches become the faces of the elongate solar cells. Alternatively, the trenches may be formed nearly through the wafer, for example greater than 95% of the wafer thickness or to within about 50 μm or less of the rear surface of the wafer. The small portion of remaining wafer at the bottom of the trench may assist in maintaining the separation of the elongate substrates during subsequent processing steps.

An n-type (or n-type) dopant is diffused into both sidewalls of the trenches to achieve sheet resistance Rₛ in the range of between about 40Ω/□ and about 200Ω/□, therefore providing doping on the faces of the elongate substrates. A passivating silicon nitride is deposited on the faces and the n-type (or p-type) dopant is driven in at a high temperature in order to adjust the doping profiles of the diffused regions on both sides of the wafer and on the faces of the elongate substrates.

Next, as depicted in FIG. 14B, the silicon oxide and silicon nitride layers are then etched with an etchant that etches the silicon oxide faster than the silicon nitride to form a recess 1407.

A local-oxidation of silicon (LOCOS) oxidation is performed, wherein oxide grows where the silicon nitride is not on silicon, to form the structure as depicted in FIG. 14C with silicon oxide protrusions 1409.

Next, the silicon nitride and silicon oxide are etched sequentially to expose the doped edge 1401 of the elongate substrate 1400, thereby exposing a fractional portion of the surface area of the edge as depicted in FIG. 14D. The fraction of the surface area of each substrate that is exposed may be selected between about 0.01% and about 99% of the total surface area of the edges, e.g. about 1%, 10%, 25%, 50%, 75%, 90% 95%, 98% or about 99%.

A metal layer is then evaporated onto the edge 1401 to form a fractional contact 1411 to the elongate solar cell 1400, as depicted in FIG. 14E. The metal may be evaporated at an angle 710 with respect to the faces, for example 45° as depicted in FIG. 7. Depending on the method of depositing the metal layer, the metal may also form on a small portion of the faces of the elongate cells, for example as depicted in FIG. 14F.

The plurality of elongate solar cells held in the frame of the semiconductor wafer may then be separated from the wafer frame in further processing to form a plurality of individual separated elongate solar cells, each elongate solar cell having fractional edge contacts.

In other arrangements of this example, a stack of silicon oxide, silicon nitride, silicon oxide, and silicon nitride is deposited onto the edge. In this arrangement, the stack is firstly etched with an etchant that attacks oxide much faster than nitride (e.g. buffered oxide etch), then next etched with a chemical that attacks nitride faster than oxide (e.g. phosphoric acid). This provides a cleaner structure without the overhang shown in the FIG. 14B. The LOCOS oxidation can then be undertaken and the process continued as above.

The process of this example are particularly suited to larger contact fractions, greater than say about 50%, as this requires the formation of smaller recesses.

Although embodiments of the present invention have been described above in terms of doping silicon using thermal diffusion, it will be apparent to those skilled in the art that the invention can be applied to other semiconductors, and that doping can be achieved by any of a variety of different methods, including ion implantation, for example.

Many modifications will be apparent to those skilled in the art without departing from the scope of the present invention as hereinbefore described with reference to the accompanying drawings.

It will be appreciated that the methods and solar cell devices described/illustrated above at least substantially provide an improved solar cell comprising a fractional edge contact.

The processes, methods and solar cell devices described herein, and/or shown in the drawings, are presented by way of example only and are not limiting as to the scope of the invention. Unless otherwise specifically stated, individual aspects and components of the processes, methods and solar cell devices may be modified, or may have been substituted therefore known equivalents, or as yet unknown substitutes such as may be developed in the future or such as may be found to be acceptable substitutes in the future. The processes, methods and solar cell devices may also be modified for a variety of applications while remaining within the scope and spirit of the claimed invention, since the range of potential applications is great, and since it is intended that the present processes, methods and solar cell devices be adaptable to many such variations.

1. An elongate solar cell, comprising a semiconductor body having two mutually opposed faces, at least one of the faces being an active face for receiving incident light, and two mutually opposed edges substantially orthogonal to the faces, the edges comprising electrical contacts thereon for conducting electrical current generated by the solar cell from the light;
wherein the electrical contact to at least one of the edges includes an electrically conductive material that contacts a fractional portion of the at least one edge of the semiconductor body to improve the performance of the solar cell.

2. The elongate solar cell as claimed in claim 1, wherein the electrically conductive material contacts a fractional portion of the at least one edge between about 0.01% and about 99% of the surface area of the edge.

3. The elongate solar cell as claimed in claim 2, wherein the electrically conductive material contacts a small portion of the at least one edge between about 0.01% and about 50% of the surface area of the edge.

4. The elongate solar cell as claimed in any one of claims 1 to 3, wherein the electrically conductive material is of elongate form and substantially centrally disposed along a longitudinal axis of the at least one edge of the semiconductor body.

5. The elongate solar cell as claimed in any one of claims 1 to 3, wherein the electrically conductive material contacts the semiconductor body at mutually spaced regions of the edge, the regions of the edge not contacted by the electrically conductive material being contacted by a dielectric material.

6. The elongate solar cell as claimed in claim 5, wherein the regions are of elongate form.

7. The elongate solar cell as claimed in claim 5, wherein the regions are of elongate form, mutually parallel, and inclined to a longitudinal axis of the at least one edge.

8. The elongate solar cell of claim 5, wherein the regions are of non-elongate form and distributed over the at least one edge.

9. The elongate solar cell as claimed in any one of claims 1 to 8, wherein the electrically conductive material contacts less than about one half of the surface area of the edge of the semiconductor body.

10. The elongate solar cell as claimed in claim 9, wherein the electrically conductive material contacts less than one half of the surface area of the edge of the semiconductor body.

11. The elongate solar cell as claimed in claim 10, wherein the electrically conductive material contacts substantially less than one half of the surface area of the edge of the semiconductor body.

12. The elongate solar cell as claimed in claim 11, wherein the electrically conductive material contacts substantially less than about 10% of the surface area of the edge of the semiconductor body.

13. The elongate solar cell as claimed in claim 12, wherein the electrically conductive material contacts substantially less than about 1% of the surface area of the edge of the semiconductor body.

14. An elongate solar cell comprising:
a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light;
wherein at least one of the edges of the elongate solar cell comprises a plurality of mutually spaced doped regions so that the at least one edge is doped discontinuously to improve the performance of the solar cell.

15. The elongate solar cell as claimed in claim 13 wherein at least one active face comprises a doped region of a first polarity (either p-type or n-type) and at least one of the edges is doped to form doped regions of a second polarity opposite to the first polarity (either n-type or p-type respectively), wherein the doped region of the at least one face intersects or abuts at least one of the doped regions of the at least one edge.

16. The elongate solar cell as claimed in claim 15 wherein the doped regions in the at least one edge occupy a fractional portion of the at least one edge.

17. The elongate solar cell as claimed in claim 16 wherein the fractional portion comprises between about 0.01% and about 99% of the surface area of the at least one edge.

18. The elongate solar cell as claimed in claim 17 wherein the fractional portion comprises between about 0.01% and about 50% of the surface area of the at least one edge.

19. The elongate solar cell as claimed in claim 17 wherein the fractional portion comprises between about 50% and about 99% of the surface area of the at least one edge.

20. The elongate solar cell as claimed in any one of claims 13 to 19 wherein the doped regions in the at least one edge form respective p-n junctions with the doped region of the corresponding at least one face.

21. A process for producing an elongate solar cell, the elongate solar cell comprising a semiconductor body having two mutually opposed faces, at least one of the faces being an active face for receiving incident light, and two mutually opposed edges substantially orthogonal to the faces, the edges comprising electrical contacts thereon for conducting electrical current generated by the solar cell from the light;
the process comprising forming an electrical contact to at least one of the edges, the electrical contact comprising an electrically conductive material that contacts only a fractional portion of the at least one edge of the semiconductor body to improve the performance of the solar cell.

22. The elongate solar cell as claimed in claim 21, wherein the electrically conductive material contacts a fractional portion of the at least one edge between about 0.01% and about 99% of the surface area of the edge.

23. The elongate solar cell as claimed in claim 21, wherein the electrically conductive material contacts a small portion of the at least one edge between about 0.01% and about 50% of the surface area of the edge.

24. The process as claimed in claim 21, comprising forming the electrically conductive material in elongate form and substantially centrally disposed along a longitudinal axis of the at least one edge of the semiconductor body.

25. The process as claimed in claim 21 wherein the contact regions are of elongate form.

26. The process as claimed in claim 21 the contact regions are of non-elongate form and are distributed over the at least one edge

27. The process as claimed in any one of claims 21 to 26 wherein the electrically conductive material contacts the semiconductor body at mutually spaced contact regions of the edge.

28. The process as claimed in claim 27 wherein regions of the edge not contacted by the electrically conductive material contacted by a dielectric material.

29. The process as claimed in any one of claims 21 to 28 further comprising
forming a dielectric or electrically insulating coating on the at least one edge of the semiconductor body, wherein the coating comprises one or more openings therein to expose a fractional portion of the at least one edge of the semiconductor body.

30. The process as claimed in claim 29 further comprising forming the electrically conductive material in the one or more openings to contact respective contact regions of the at least one edge exposed by the openings.

31. The process as claimed in either of claims 29 to 30 further comprise forming heterojunction electrical contacts within the openings.

32. The process as claimed in any one of claims 29 to 31 wherein the openings are formed by depositing the electrically conductive material over the coating, and driving the electrically conductive material through the coating at mutually spaced locations to form the openings.

33. The process as claimed in claim 32 wherein the electrically conductive material is driven through the coating only at mutually spaced regions of the coating by localised heating by a process comprising selectively heating corresponding mutually spaced regions of the electrically conductive material.

34. The process as claimed in claim 32 wherein the electrically conductive material is deposited only at mutually spaced regions on the coating, and is locally driven through the coating using a process of uniform heating.

35. The process as claimed in claim 32 comprising selectively doping only those regions of the at least one surface of the semiconductor body exposed by the openings, and forming the electrically conductive material to contact the resulting doped regions.

36. The process as claimed in any one of claims 21 to 35 wherein the electrically conductive material comprises a dopant species.

37. The process as claimed in claim 36 wherein the contact regions are doped by selectively heating corresponding regions of the electrically conductive material formed over the dielectric coating to selectively drive the heated regions of the electrically conductive material through the dielectric coating to contact the edge of the semiconductor body and to drive the dopant species into the semiconductor body.

38. The process as claimed in claim 36 wherein the contact regions are doped by selectively depositing the electrically conductive material at mutually spaced locations on the dielectric coating, and subsequently heating the electrically conductive material to drive it through the dielectric coating to contact the edge of the semiconductor body and to drive the dopant species into the semiconductor body.

39. The process as claimed in any one of claims 21 to 38 wherein the faces of each elongate solar cell are doped with a dopant of a first polarity (either p-type or n-type), and an edge of the elongate solar cell doped discontinuously in mutually spaced doped regions with a dopant of a second polarity opposite to the first polarity (either n-type or p-type respectively), wherein the doped regions of the faces and the doped regions of the edge intersect or abut over only a relatively small portion of the length of each intersection of the edge and the corresponding face.

40. A process for producing an elongate solar cell, the elongate solar cell comprising a semiconductor body comprising two mutually opposed faces, at least one of the faces being an active face for receiving incident light, and two mutually opposed edges substantially orthogonal to the faces, the edges comprising electrical contacts thereon for conducting electrical current generated by the solar cell from the light; the process comprising forming a plurality of mutually spaced doped regions in at least one of the edges so that the at least one edge is doped discontinuously to improve the performance of the solar cell.

41. The process as claimed in claim 40 wherein the doped regions in the at least one edge occupy between about 0.01% and less then 100% of the at least one edge.

42. The process as claimed in claim 40 wherein the doped regions in the at least one edge occupy approximately equal to or less than about one half (≈≦50%) of the at least one edge.
